(19) United States
(12) Patent Application Publication
(10) Pub. No.: US 2026/0044074 A1
(43) Pub. Date: Feb. 12, 2026

(54) ACCEPTOR-SUBSTITUTED EUV PAGS WITH HIGH ELECTRON AFFINITY

(71) Applicant: Merck Patent GmbH, Darmstadt (DE)

(72) Inventors: Ralph R. Dammel, Springfield, PA (US); Gregor Larbig, Gelnhausen (DE); Kun Si, Hillsborough, NJ (US)

(21) Appl. No.: 19/148,146

(22) PCT Filed: Feb. 19, 2024
(86) PCT No.: PCT/EP2024/054110

§ 371 Date: Jul. 15, 2025

Related U.S. Application Data
(60) Provisional application No. 63/486,058, filed on Feb. 21, 2023.

(51) Int. Cl. G03F 7/004; G03F 7/00; G03F 7/038; G03F 7/039; G03F 7/16

(52) U.S. Cl. CPC G03F 7/0045; G03F 7/0382; G03F 7/0392; G03F 7/168; G03F 7/70033; G03F 7/70383

(57) ABSTRACT

Compounds of structure (I) are described wherein, R₁, R₂, R₁ₐ and R₂ₐ are independently selected from H, nitro, cyano, and an alkylsulfonyl, wherein at least two of R₁, R₂, R₁ₐ and R₂ₐ are independently selected from nitro, cyano, and an alkylsulfonyl, and X− is not a halide, tosylate, trifluoromethylsulfonate, tetrafluoroborate, an aryl-substituted borates, hexafluorophosphate, hexafluoroarsenate, acetate, trifluoroacetate, methane sulfonate, C-2 to C-20 linear unsubstituted alkyl sulfonates, naphthalenesulfonate, and camphorsulfonate. Also described are EUV negative and positive chemically amplified photoresist compostions containing said compound and the process of using these photoresist to pattern a substrate.

### FIELD

The disclosed and claimed subject matter relates to a chemically amplified organic resist material that contains a class of photoacid generator (PAG) which is designed to enhance the sensitivity for high resolution patterning using e-beam or EUV radiation of 13.5 nm wavelength, and processes for using the same.

### BACKGROUND

Chemically amplified resists are the dominant resist type used in 248 nm, 193 nm, and 193 nm immersion lithography. In these chemically amplified resists, the solubility change of the resist is split into two reactions. The first step is a photoreaction, in which a photon is absorbed by a photoacid generator (PAG) which decomposes with formation of a photoacid. The photoacid then catalyzes a chemical reaction which leads to the solubility change of the photoresist, for example, making the exposed areas more soluble in a developer for the case of a positive-tone photoresist. The solubility change may be caused by a deprotection reaction of a group pendant from a polymer backbone, for example, an acetal-protected phenol or a tertiary alcohol ester of a carboxylic acid, which leads to the formation of a phenolic OH group or a carboxylic acid, rendering the polymer soluble in aqueous base developers or insoluble in an organic solvent developer. These reactions often occur during a post exposure bake (PEB) step. Since the photoacid acts as a catalyst only and is not consumed in the reaction, it can catalyze many such reactions: the original photo-event is amplified by the number of reactions catalyzed per acid—hence the name chemical amplification.

Commonly used PAGs include triphenylsulfonium and diphenyliodonium salts of strong acids, including but not limited to perfluoroalkyl sulfonic acids, and their derivatives. For the above-mentioned UV wavelengths, the photoacid formation occurs via absorption of a photon into one of the absorption bands of the PAG, transitioning it into an excited state which is unstable and decomposes into a radical and a radical cation, with the latter reacting further to generate the proton needed to form the catalytic species. This mechanism has been described in some detail in the literature. [John L. Dektar and Nigel P. Hacker, J. Am. Chem. Soc. 1990, 112, 6004-6015]

The use of chemically amplified resists has been extended to Extreme UV (EUV) with a wavelength of 13.5 nm or a photon energy of 91.6 eV. At this wavelength, the absorption of the photon leads to a primary ionization event in which an electron is ejected from an atom at high energy. This electron then collides with other atoms, leading to further ionization events which generate secondary electrons. In this electron cascade the energy of the original photon is dissipated over a limited area around the original absorption event in the form of electron and positively charged species (“holes”) as well as electronic and thermal excitations. The size of this area is limited by the path length of the primary and secondary electrons, which has been estimated to be of the order of 2-3 nanometers.

At the lower energy UV lithographic wavelengths (i.e., 248 and 193 nm), the polymeric component of the resist is largely transparent at the exposure wavelength and absorption occurs predominantly by the PAG. However, at the EUV energy, all matter is absorbing. Specifically, photon absorption and ensuing ionization can occur in any of the atoms constituting the photoresist, not only in the PAG. This absorption occurs largely independent of the chemical environment of the ionized atom: instead, it depends only on the atomic composition of the photoresist. The absorbance of an EUV resist can be directly calculated from the individual atomic absorption cross sections and the film density, without taking the chemical environment of the atoms into account. [Roberto Fallica, Jarich Haitjema, Lianjia Wu, Sonia Castellanos, Albert M. Brouwer, Yasin Ekinci, J. Micro/Nanolith. MEMS MOEMS 17(2), 023505 (2018), doi: 10.1117/1.JMM.17.2.023505]

This results in a key difference in the mechanism of acid generation between EUV and the longer UV lithographic wavelengths: in EUV, the direct absorption of a photon by the PAG is no longer the primary mechanism of photoacid generation. During the exposure, the EUV photon absorption generates a steady state of electrons and holes, with the electrons losing energy in successive collisions until they have reached energies near the thermal equilibrium, or they have recombined with a hole. The PAG comes into play again at the lower energies in the electron cascade when its cation can capture an electron, leading to the formation of a free radical. This free radical is unstable and decomposes into uncharged reaction products, as shown in Eq (1) for the parent triphenyl sulfonium and diphenyl iodonium cations.

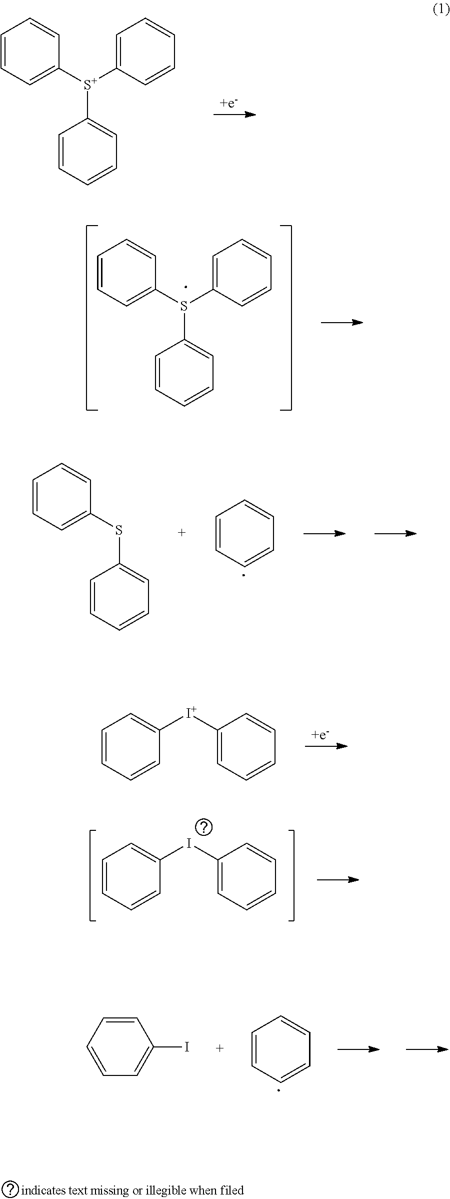

As a result of the electron capture, an electron is removed from the electron/hole equilibrium that is formed for the duration of the exposure, leaving a hole behind. The cationic species corresponding to these holes then react further to generate the proton needed to form the catalytic species (i.e., the dissociated or undissociated photoacid). The kinetics of this process have been studied in the literature, and the rates of acid formation predicted by the kinetic model are in excellent accordance with experiment. [Craig D. Higgins, Charles R. Szmandal, Alin Antohe, Greg Denbeaux, Jacque Georger2, and Robert L. Brainard, Japanese Journal of Applied Physics 50 (2011) 036504, 10.1143/JJAP.50.036504, DOI: 10.1143/JJAP.50.036504]

In the above-referenced kinetic model, the concentration of the hole species R is reduced from the steady-state concentration F[R₊, e⁻] either by acid formation or by recombination with electrons according to Eq. (2).

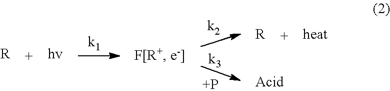

From the point of view of acid formation, electron/hole recombination is a parasitic process that reduces acid formation efficiency. The number of recombination events can be reduced if electrons are removed from the steady state through electron capture by the PAG. Every electron capture event leaves behind a hole that is free to react further to form a photoacid. The more efficient the electron capture is, the higher the acid yield will be.

One parameter that one might expect to predict the efficiency of electron capture by a PAG is the energy balance on capture of an electron, also known as its electron affinity. According to a widely accepted generalization of Koopman's theorem, [Tjalling Koopmans, Physica. 1 (1-6): 104-113. doi:10.1016/S0031-8914(34)₉₀₀₁₁-2.], the electron affinity can be estimated by the LUMO energy obtained from quantum chemical calculations within the limits of the single-electron self-consistent field (SCF) model. Table 1 lists the calculated LUMO values for a number of sulfonium and iodonium PAGs. Inspection of the table shows that iodonium salts generally have higher electron affinities than sulfonium salts.

A result of the calculations summarized in Table 1 is that iodonium salts can have significantly higher electron affinities than sulfonium salts. Another advantage of iodonium salts is that the iodine atom has a very high EUV absorption cross section. While this may be only of minor importance with respect to raising the overall EUV absorbance of the resist film, as the PAG is only a small fraction of its total mass, it may contribute to increased photospeed to some extent due to a contribution of direct absorbance of the initial photon into the PAG.

In the above-referenced kinetic study [Higgins et al.], the acid formation efficiencies of two PAGs, bis(4-(tert-butyl)phenyl)iodonium nonafluorobutane sulfonate and triphenylsulfonium nonafluorobutane sulfonate, were determined to be 5.6 and 4.6 acids/absorbed photon, respectively. This is in accordance with other studies which have shown that diphenyl iodonium salts lead to higher EUV photospeeds than triphenylsulfonium salts [Martin Glodde, Dario L. Goldfarb, David R. Medeiros, Gregory M. Wallraff, and Gregory P. Denbeaux, Journal of Vacuum Science & Technology B: Microelectronics and Nanometer Structures Processing, Measurement, and Phenomena 25, 2496 (2007); doi: 10.1116/1.2779045], [Dario L. Goldfarb, Ali Afzali-Ardakani, Martin Glodde, Proc. SPIE 9779, Advances in Patterning Materials and Processes XXXIII, 97790A (25 Mar. 2016); doi: 10.1117/12.2218457], a finding that is consistent with the EA values found in Table 1.

TABLE 1
LUMO energies of sulfonium and iodonium cations as calculated by the PM3 method.
All geometries were optimized by the Polak-Ribiere conjugate gradient method to an RMS
gradient of 0.1 kcal/(Å mol)

| | | LUMO | | | LUMO |
|---|---|---|---|---|---|
| Sulfonium cations | LUMO [eV] | vs.parent | Iodonium cations | LUMO [eV] | vs.parent |
| tris(4-t- | −4.71 | 0.11 | 2-n-butylsulfonyl | −4.82 | 0.67 |
| butyl)sulfonium | | | | | |
| triphenylsulfonium | −4.82 | 0.00 | 2-nitro | −5.28 | 0.21 |
| (parent) | | | | | |
| Onium 1 | −4.97 | −0.15 | 4,4′-bis-t-butylphenyl | −5.29 | 0.21 |
| Onium 2 | −5.12 | −0.30 | 3-n-butylsulfonyl | −5.43 | 0.06 |
| Onium 5 | −5.13 | −0.32 | 4-n-butylsulfonyl | −5.44 | 0.05 |
| Onium 3 | −5.31 | −0.49 | 3,3′-bis-n-butylsulfonyl | −5.46 | 0.03 |

| | | | |
|---|---|---|---|
| 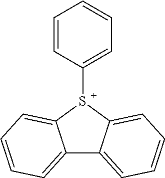 Onium 1 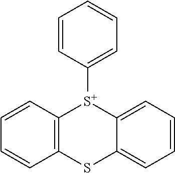 [SMILES: c1ccc([S+]2c3ccccc3Sc3ccccc32)cc1] Onium 2 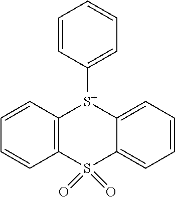 [SMILES: O=S1(=O)c2ccccc2[S+](c2ccccc2)c2ccccc21] Onium 3 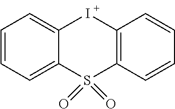 Onium 4 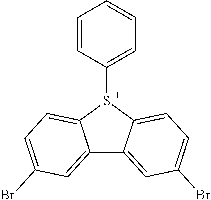 Onium 5 | onium 4 diphenyliodonium (parent) 2,2′-dinitro 2-CN 2-NO2 2,2′-CN 4-CN 3-CN 4,4′-bis-n-butylsulfonyl 3-(n-butyl sulfonyl)-4- nitro 4-(n-butyl sulfonyl)-3- nitro 3-nitro 2,2′-CF₃ 4-nitro 3,4′-CN 4,4′-CN 3,3′-CN 4-(n-butylsulfonyl)-4′- nitro 3,3′-CF₃ 4,4′-CF₃ bis(2,4,6-trifluorphenyl) 3,3′ dinitro 3,4′-dinitro 4,4′-dinitro | −5.47 −5.49 −5.50 −5.60 −5.69 −5.70 −5.72 −5.72 −5.75 −5.77 −5.79 −5.85 −5.89 −5.92 −5.93 −5.93 −5.97 −5.97 −6.03 −6.07 −6.13 −6.19 −6.33 −6.33 | 0.02 0.00 −0.01 −0.11 −0.20 −0.21 −0.22 −0.23 −0.26 −0.28 −0.29 −0.36 −0.40 −0.43 −0.44 −0.44 −0.48 −0.48 −0.54 −0.58 −0.64 −0.69 −0.83 −0.83 |

In one of the above-referenced studies, [Goldfarb et al.] the electron affinity EA and electrochemical reduction potential Ep of the PAGs were investigated as predictors of EUV photospeeds. EA values, as determined from the LUMO values, and Ep values, as determined experimentally, were found to be highly correlated in a linear relationship. However, not all PAG photospeeds were correctly predicted by the EA or Ep values. The authors came to the conclusion that “[a]lthough a link between such fundamental studies and actual EUV photospeed could not be established, a remarkable improvement in EUV sensitivity was detected for the PAG group with photoelectron trapping properties, compared to its DUV performance.” It is thus concluded from the presumed electron capture mechanism of acid formation from PAGs in EUV exposure and from the available literature data that electron affinity values may provide a guide in pre-selecting highly efficient EUV PAGs but that there are other factors influencing PAG performance as well.

### DETAILED DESCRIPTION OF DRAWINGS

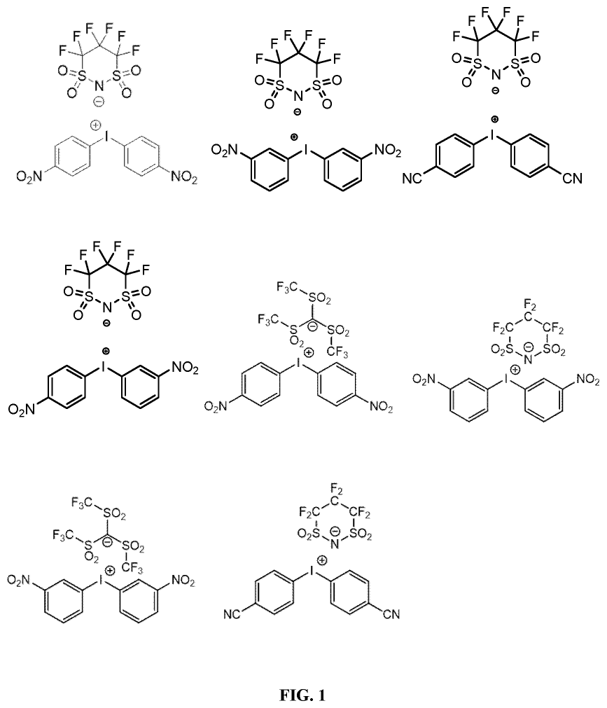

FIG. 1 Examples of specific compounds of structure (I), (Ia), (Ib) and (Ic).

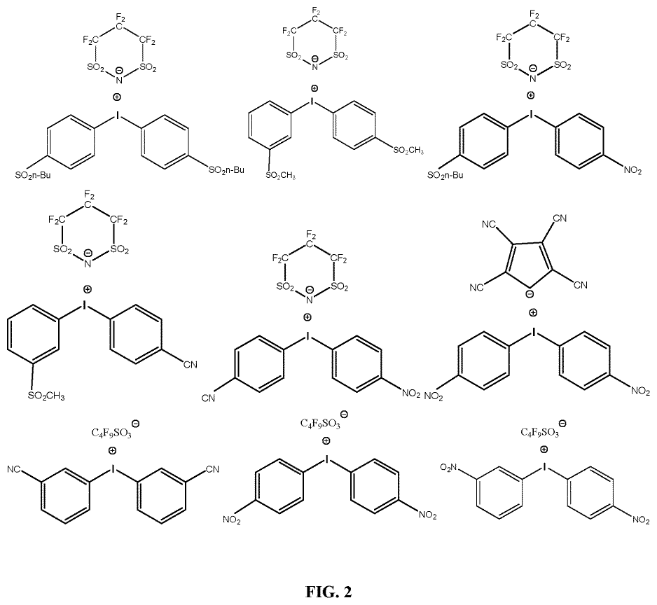

FIG. 2 Examples of specific compounds of structure (I), (Ia), (Ib) and (Ic).

### SUMMARY OF INVENTION

This invention pertains to a compound of structure (I), wherein R₁, R₂, R₁ₐ and R₂ₐ are independently selected from H, nitro, cyano, and an alkylsulfonyl, wherein at least two of R₁, R₂, R₁ₐ and R₂ₐ are independently selected from nitro, cyano, and an alkylsulfonyl, and X⁻ is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate. Other aspects of this invention are EUV negative and positive chemically amplified photoresist compositions containing said compound and the process of using these photoresist to pattern a substrate.

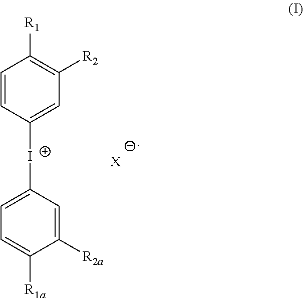

The present invention describes PAGs with a higher acid formation efficiency under ionizing radiation exposure, said higher efficiency resulting from the increased electron affinity these PAGs exhibit as a result of acceptor substitution of the PAG cation. A higher number of catalytic acids formed per EUV photon or electron impact is desirable because it will increase photoresist sensitivity, leading to higher throughput, and reduce stochastic effects on line width roughness. Another aspect of the invention is the use of the compound of structure (I) and any of its embodiments disclosed herein as a photoacid generator. Yet another aspect of the invention is the use of any one of the compositions disclosed herein as a photoresist on a substrate.

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or,” unless specifically stated otherwise. Furthermore, the use of the term “including,” as well as other forms such as “includes” and “included,” is not limiting. Also, terms such as “element” or “component” encompass both elements and components comprising one unit and elements or components that comprise more than one unit, unless specifically stated otherwise. As used herein, the conjunction “and” is intended to be inclusive and the conjunction “or” is not intended to be exclusive unless otherwise indicated. For example, the phrase “or, alternatively” is intended to be exclusive. As used herein, the term “and/or” refers to any combination of the foregoing elements including using a single element.

The term C-1 to C-4 alkyl embodies methyl and C-2 to C-4 linear alkyls and C-3 to C-4 branched alkyl moieties, for example as follows: methyl (—CH₃), ethyl (—CH₂—CH₃), n-propyl (—CH₂—CH₂—CH₃), isopropyl (—CH(CH₃)₂, n-butyl (—CH₂—CH₂—CH₂—CH₃), tert-butyl (—C(CH₃)₃), isobutyl (CH₂—CH(CH₃)₂, 2-butyl (—CH(CH₃)CH₂—CH₃). Similarly, the term C-1 to C-8 embodies methyl, C-2 to C-8 linear, C-3 to C-8 branched alkyls, C-4 to C-8 cycloalkyls (e.g., cyclopentyl, cyclohexyl etc) or C-5-C-8 alkylenecycloalkyls (e.g. —CH₂-cyclohexyl, CH₂—CH₂-cyclopentyl etc.).

The term C-2 to C-8 alkylene embodies C-2 to C-8 linear alkylene moieties (e.g., ethylene, propylene etc.) and C-3 to C-8 branched alkylene moieties (e.g., —CH(CH₃)—, —CH(CH₃)—CH₂—, etc.).

The term C-2 to C-4 alkylene embodies C-2 to C-4 linear alkylene moieties and C-3 to C-4 branched alkylene moieties.

The term C-2 to C-8 perfluoroalkylene embodies C-2 to C-8 linear perfluoroalkylene moieties and C-3 to C-8 branched perfluoroalkylene moieties.

The term C-2 to C-4 perfluoroalkylene embodies C-2 to C-4 linear perfluoroalkylene moieties and C-3 to C-4 branched prerfluoroalkylene moieties.

The term alkylsulfonyl unless otherwise indicated encompasses C-1 to C-8 alkyl moieties, which in turn encompasses C-1 to C-8 linear alkyls, C-3 to C-8 branched alkyls, C-3 to C-8 cyclic alkyls and C-4 to C-8 alicyclic alkyls, attached to sulfonyl.

The phrase X⁻ is an anion of an acid with a pKₐ lower than 0, as used herein excludes acids having a pKₐ lower than 0 but which also have a corresponding anion which is nucleophilic (e.g. HI, HCl, HBr, HF). Such nucleophilic anions would attack intermediate carbocations forming a stable compound (e.g. alkyl halides such a tert-butyl halides), which terminates the chemical amplification chain reaction, and preventing regeneration of the catalytic proton (H). The following references, discusses the mechanism of chemical amplification (Polymers for Microelectronics ACS Symposium Series ACS, (1993), Chapter 1 Chemically Amplification Mechanisms for Microlithography, E. Reichmanis et al, pages 3) (Chemical Amplification Resists for Microlithography Adv Polymer Sci, Hiroshi Ito (2005) 172, page 37). Examples of suitable non-nucleophilic anion are described below.

The present invention relates to PAGs which have been designed for and shown to exhibit high photospeed for ionizing radiation, such as x-ray, EUV, particle beam, or e-beam, that generate electrons as a result of their energy dissipation mechanism which can be captured by iodonium salts. Iodonium derivatives which have been selectively substituted with acceptor substituents in order to increase their electron capture efficiency by raising their electron affinity beyond that of the parent (i.e. lacking the acceptor substituents) compound.

Among these acceptor substituents, nitro, cyano, and alkylsulfonyl substituents in the 3- and 4-positions have been found to be particularly effective. However, it is not only the nature but also the position of the substituents that is important. Nitro-substituents in the 2-position lead to lower calculated EA values as well as slower photospeeds. The (2-nitrophenyl)phenyliodonium ion has lower electron affinity than the parent diphenyliodonium ion, and the electron affinity of the 2,2′-dinitrophenyl derivative is very close to that of the parent despite substitution by two strong acceptors. The n-butylsulfonyl group, which acts as a weak electron donor in the 3- and 4-positions, is a strong electron donor when in 2-position. This “ortho effect” is presumed to be a result of the negative charge of the oxygen atoms in the nitro- or sulfonyl group which are in close proximity to the central iodonium, donating electron density to it and thus reducing the latter's positive charge and hence its electron affinity. The ortho effect may also be contributing to the electron affinity of the 2,2′-dicyano derivative, although in this case the partial negative charge is further removed from the central iodine and there are no interactions with a lone pair. It is notable that 3- and 4-acceptor substitution leads to almost equivalent increases in electron affinity, something that is not normally expected from the typical substituent effects seen in aromatic systems. The n-butylsulfonyl substituent, chosen here as a general stand-in for all alkylsulfonyl substituents, is decreasing the electron affinity in monosubstitution (Table 1), but leads to a high electron affinity when situated in the 4-positon and combined with a 4′ nitro substituent. Alkylsulfonyl substituents are of interest since by selecting an appropriate length of an alkyl chain it is possible to improve the solubility characteristics of the iodonium salts. The trifluoromethyl CF₃ substituent acts as a strong acceptor in the 3- and 4-positions, but also leads to a significant increase in electron affinity when in the 2-positon: as a “hard” substituent (i.e., one with low polarizability), it is much less susceptible to the ortho effect.

There are a number of compounds in Table 1 for which the EA is not a valid predictor of the observed EUV photospeed. A test of a bis(2,4,6-trifluorophenyl) iodonium PAG was reported in the literature and was found to have very low EUV photospeed. [Goldfarb et al.] In the same reference, PAGs Onium 1, 2, 3 and 5 were found to have slower or only equivalent photospeed as the parent compound, although calculations predict a significantly higher EA.

### EUV PAG Component

The iodonium ions are combined with suitable counter-anions to form iodonium salts. For the purpose of high-resolution photolithography, these anions must be strong and non-nucleophilic acids that also have low diffusivity and volatility. In terms of their acidity, the photoacids should have a pKa of −1 or below on the 1,2-dichloroethane acidity scale [Eno Paenurk, Karl Kaupmees, Daniel Himmel, Agnes Kütt, Ivari Kaljurand, Ilmar A. Koppel, Ingo Krossing and Ivo Leito, Chem. Sci., 2017, 8, 6964]. Sulfonic acids have been preferred since they show low nucleophilicity and do not react with the cationic intermediates which are formed during the solubility changing reaction. The absence of such side reactions is important because addition of the acid anion to the cationic species will lead to a neutral molecule, i.e., the acid catalyst is consumed and the chain reaction of chemical amplification ends.

Early chemically amplified resists used antimony hexafluoride, arsenic hexafluoride, or hexafluorophosphate anions. Of these, PF₆⁻ is undesirable because phosphorus is a dopant, and AsF₆⁻ because of the high toxicity of arsenic.

For high resolution applications, it is also desirable that the acids do not exhibit high diffusivity. For example, triflic acid is a strong catalyst with low nucleophilicity, but it is quite diffusive and also has high vapor pressure, which can lead to re-deposition of acid from highly exposed regions to area that were intended to be unexposed [Thomas Wallow, Marina Plat, Zhanping Zhang, Brian MacDonald, Joffre Bernard, Jeremias Romero, Bruno La Fontaine, Harry J. Levinson, Proc. SPIE 6519, Advances in Resist Materials and Processing Technology XXIV, 65190T, 2007; doi: 10.1117/12.712338]. Triflic acid is thus not a good candidate for high resolution resists.

In one embodiment of the inventive PAG, composition and processes, suitable counteranions include but are not limited to:
Antimony hexafluoride; Per- and polyfluoro alkane sulfonates, including but not limited to perfluorobutanesulfonate (PFBS), hexafluoropropane sulfonate, or oxa-substituted derivatives including but not limited to 1,1,2-trifluoro-2-(trifluoromethoxy)ethane sulfonate (TTES); Anions of methide and imide superacids such as tris(perfluoroalkylsulfonyl)methides, in particular tris[(trifluoromethyl)sulfonyl]methide (C1) and tris[(nonafluoro-n-butyl)sulfonyl]methide (C4), bis(perfluoroalkylsulfonyl)imide anions, in particular bis(trifluoromethanesulfonyl)imide anion (N1), bis(nonafluoro-n-butanesulfonyl)imide anion (N4), and the cyclic 4,4,5,5,6,6-hexafluorodihydro-1,1,3,3-tetraoxide-4H-1,3,2-dithiazine (NC3).

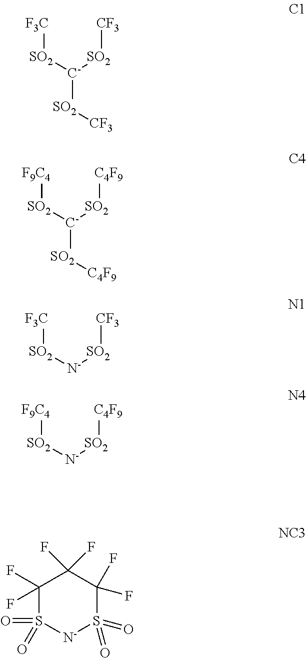

In another aspect of this embodiment other suitable counteranions are acid anions containing fluorinated aromatic systems, including but not limited to fully and partially substituted benzenesulfonates bearing fluorine and trifluoromethyl substituents.

In another aspect of this embodiment other suitable counteranions are polymer bound acids, in which a sulfonate anion is connected to a polymer backbone by a linker group, said linker group not containing an aromatic ring directly bound to the SO₃⁻ group. In one preferred embodiment, the linker group includes a CF₂ group on a carbon atom next to the sulfonate. In another preferred embodiment, the pendant acid anion is a bis-sulfonyl imide anion which bears one perfluoroalkyl substituent, most preferably CF₃ or C₄F₉, and a linker group binding it to a polymer backbone, with the linker group containing carbon atoms which are optionally also per- or poly-fluorinated.

Non-PFAS anions such as polycyano-substituted cyclopentadienide anions, in particular pentacyano, tetracyano-monocarboxylate, and tetracyanomethoxy cyclopentadienide anions [Martin Glodde, Sen Liu and Pushkara Rao Varnasi, J. Photopol. Sci. Techn. 23(2), 173-184 (2010) and U.S. Pat. No. 7,655,379 B2] or acceptor-substituted thiophene sulfonates as described in Liu et al. [Sen Liu, Martin Glodde and Pushkara Varanasi, Proc. SPIE 7639, 76390D (2010); DOI: 10.1117/12.846600], US2009181319 A1 and U.S. Pat. No. 8,617,791 B2.

In another aspect of this embodiment other suitable counteranions as described in WO 2009/087027 A2 which discloses PAG's of formula P⁺A⁻. where the group of A⁻ includes pentacyanocylopentadienide and various tetracyanocarboxylate ions, and where P⁺ is an onium salt, particularly an iodonium salt, which may optionally be nitro-substituted. However, WO 2009/087027 A2 does not teach or suggest the combination of the cations of the present invention with these anions, since it lists nitro as one of many substituents on P⁺ (both electron donating and withdrawing) and does not distinguish between substitution in the 2, 3, or 4-positions. As the present invention has surprisingly found, only nitro-substitution in the 3- and 4-positions, and particularly nitro-disubstitution, results in higher electron affinity and hence higher acid yield for such PAGs, whereas 2-substitution is actually deleterious to it and 2,2′di-substitution is ineffective.

As described herein, when pKₐ ranges are discussed these values pKₐ are ones predicted by ACD/pKₐ software version 4.0 for Microsoft windows (Advanced Chemistry development Inc 8 King Street East, Suite 107, Toronto, Ontario Canada).

One aspect of this invention is a compound of structure (I), wherein, R₁, R₂, R₁ₐ and R₂ₐ are independently selected from H, nitro, cyano, and an alkylsulfonyl, wherein at least two of R₁, R₂, R₁ₐ and R₂ₐ are independently selected from nitro, cyano, and an alkylsulfonyl, and X⁻ is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,

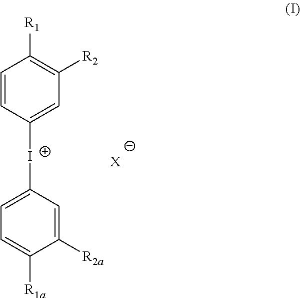

Another aspect of this invention is a compound of structure (I), compound of structure (I) wherein, either R₁ and R₁ₐ, R₂ and R₂ₐ, R₁ₐ and R₂, or R₁ and R₂ₐ are independently selected from nitro, cyano, and an alkylsulfonyl, and X⁻ is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate.

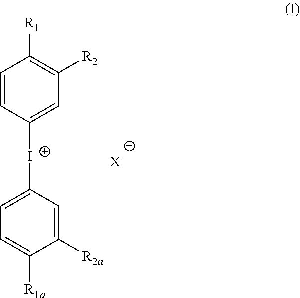

In one aspect of the inventive compound of structure (I), described above, it more specifically has structure (Ia). In one aspect of this embodiment R₁ and R₁ₐ are both nitro. In another aspect of this embodiment, R₁ and R₁ₐ are both cyano. In another aspect of this embodiment, R₁ and R₁ₐ are both an alkylsulfonyl. In another aspect of this embodiment, R₁ is nitro and R₁ₐ is cyano. In another aspect of this embodiment, R₁ is nitro and R₁ₐ is an alkylsulfonyl. In another aspect of this embodiment, R₁ is an alkylsulfonyl and R₁ₐ is cyano.

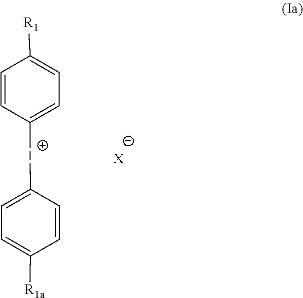

In one aspect of the inventive compound of structure (I), described above, it is more specifically has structure (Ib). In one aspect of this embodiment, R₂ and R₂ₐ are both nitro. In another aspect of this embodiment R₂ and R₂ₐ are both cyano. In another aspect of this embodiment R₂ and R₂ₐ are both an alkylsulfonyl. In another aspect of this embodiment, R₂ is nitro and R₂ₐ is cyano. In another aspect of this embodiment, R₂ is nitro and R₂ₐ is an alkylsulfonyl. In another aspect of this embodiment, R₂ is an alkylsulfonyl and R₂ₐ is cyano.

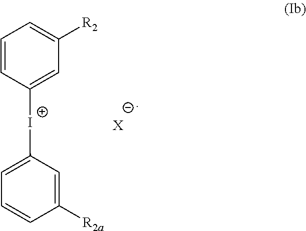

In one aspect of the inventive compound of structure (I), described above, it is more specifically has structure (Ic). In one aspect of this embodiment R₁ and R₂ₐ are both nitro. In another aspect of this embodiment R₁ and R₂ₐ are both cyano. In another aspect of this embodiment R₁ and R₂ₐ are both an alkylsulfonyl. In another aspect of this embodiment, R₁ is nitro and R₂ₐ is cyano. In another aspect of this embodiment R₁ is nitro and R₂ₐ is alkylsulfonyl. In another aspect of this embodiment R₁ is an alkylsulfonyl and R₂ₐ is cyano.

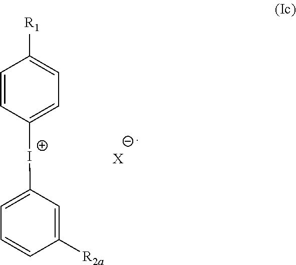

In another aspect of the inventive compounds of any one of structures (I), (Ia), (Ib) and (Ic), X⁻ is an anion of an acid having a pKₐ lower than 0. In another aspect of this embodiment X⁻ is an anion of an acid having a pKₐ lower than 1.

In another aspect of the inventive compounds of structure (I), (Ia), (Ib) and (Ic), X⁻ is an anion which is a perfluorinated or partially fluorinated alkyl sulfonate with more than 3 carbons, whose alkyl is a linear, branched or cyclic alkyl. In another aspect of this embodiment X⁻ is an anion which is a perfluorinated or partially fluorinated alkyl sulfonate with more than 3 carbons whose alkyl is a linear, branched or cyclic alkyl which comprise a heteroatom group selected from —O—, —C(═O)—, and —S(═O)₂—.

In another aspect of the inventive compounds of any one of structures (I), (Ia), (Ib) and (Ic), X⁻ is Antimony hexafluoride.

In another aspect of the inventive compounds of any one of structures (I), (Ia), (Ib) and (Ic), X⁻ is the anion of a methide or imide perfluorinated superacid. In one aspect of this embodiment, it is the anion of a methide perfluorinate superacid. In another aspect of this embodiment, it is an anion of an imide perfluorinated superacid.

In another aspect of the inventive compounds of any one of structures (I), (Ia), (Ib) and (Ic), X⁻ is perfluorobutanesulfonate (PFBS), or hexafluoropropane sulfonate.

In another aspect of the inventive compounds of any one of structures (I), (Ia), (Ib) and (Ic), X⁻ is a tris(perfluoroalkylsulfonyl)methide.

In another aspect of the inventive compounds of any one of structures (I), (Ia), (Ib) and (Ic), X⁻ is an anion selected from the group consisting of tris[(trifluoromethyl)sulfonyl]methide (C1) and tris[(nonafluoro-n-butyl)sulfonyl]methide (C4), bis(perfluoroalkylsulfonyl)imide anions, in particular bis(trifluoromethanesulfonyl)imide anion (N1), bis(nonafluoro-n-butanesulfonyl)imide anion (N4), and the cyclic 4,4,5,5,6,6-hexafluorodihydro-1,1,3,3-tetraoxide-4H-1,3,2-dithiazine (NC3).

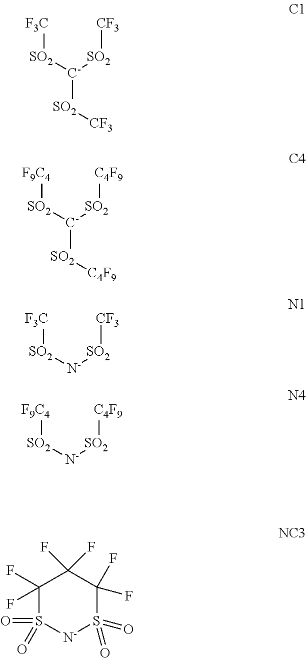

In another aspect of the inventive compounds of any one of structures (I), (Ia), (Ib) and (Ic), X⁻ is a fluorinated arylsulfonate, which is either partially or fully substituted with a substituent selected from Fluorine or a perfluoroalkyl.

In another aspect of the inventive compounds of any one of structures (I), (Ia), (Ib) and (Ic), X⁻ is a sulfonate moiety (—SO₃⁻) connected to a polymer backbone by a linker group, said linker group not containing an aromatic ring directly bound to said —SO₃⁻ moiety. In another aspect of this embodiment said —SO₃⁻ moiety is directly attached to said polymer backbone through a C-1 to C-8 linear perfluoroalkylene linker group. In another aspect of this embodiment said perfluoroalkylene linker group is selected from the group consisting of a difluoromethylene (—CF₂—) a tetrafluoro ethylene (—CF₂—CF₂—), and hexafluoropropylene (—CF₂—CF₂—CF₂—). In another aspect of this embodiment said linker group is one where a methylene moiety is directly attached to said sulfonate moiety which at its other end is either directly attached to said polymer or through a C-1 to C-4 perfluoroalkylene moiety.

In another aspect of the inventive compounds of any one of structures (I), (Ia), (Ib) and (Ic), X⁻ is a perfluoroalkylamide moiety (—N(perfluoroalkyl)⁻), either directly connected to a polymer backbone or by a linker group which is selected from the group consisting of a C-1 to C-8 alkylene, a C-1 to C-8 perfluorinated alkylene, a C-1 to C-8 partially fluorinated alkylene.

In another aspect of the inventive compounds of any one of structures (I), (Ia), (Ib) and (Ic), X⁻ is a diperfluoroalkylcarbide moiety (—C(perfluoroalkyl)₂⁻), either directly connected to a polymer backbone or by a linker group which is selected from the group consisting of a C-1 to C-8 alkylene, a C-1 to C-8 perfluorinated alkylene, and a C-1 to C-8 partially fluorinated alkylene. In another aspect of the inventive compounds of any one of structures (I), (Ia), (Ib) and (Ic), X⁻ is a polycyano-substituted cyclopentadienyl anion. In another aspect of this embodiment said polycyano-substituted cyclopentadienyl anion is selected from the group consisting of pentacyano cyclopendadienyl anion, tetracyano-monocarboxylatecyclopendadienyl anion and tetracyanomethoxy cyclopentadienyl anion. FIG. 1 and FIG. 2 shows non limiting examples of specific compounds of structure (I), (Ia), (Ib) and (Ic).

### EUV Suitable Resin Components

### Polymeric Resins for Photoresists

The inventive photoresist compositions, described herein, comprise an acid sensitive imaging polymer and an acceptor-substituted photoacid generator as described above. The imaging polymer is preferably capable of undergoing chemical transformations upon exposure of the photoresist composition to ionizing radiation whereby a differential solubility of the polymer in either the exposed regions or the unexposed regions are created. That is, the base polymers employed in the present invention include any acid sensitive polymer having acid sensitive side chains which can undergo catalytic cleavage in the presence of an acid generated by the inventive photoacid generator. The imaging polymer may be either a positive-tone imaging polymer or a negative-tone imaging polymer. In such polymers, the acid sensitivity exists because of the presence of acid sensitive side chains that are bonded to the polymer backbone. Such acid sensitive polymers including acid sensitive side chains are conventional and are well known in the art. Preferably, the imaging polymer is one suitable for use in 13.4 nm (EUV) lithography. A resist composition that operates in positive tone when developed with aqueous base developers may operate as a negative tone resist when developed with solvents, one non-limiting example for which is n-butyl acetate.

In some embodiments, of these inventive compositions, the acid sensitive side chains of the acid sensitive polymers are protected with various acid labile protecting groups that are well known to those skilled in the art. For example, the acid sensitive side chains may be protected with high activation energy protecting groups such as t-butyl ester or t-butyl carbonyl groups, a low activation energy protecting group such as acetal, ketal, or silyethers of phenolic species, or a combination of both low and high activation energy protecting groups may also be used. Most preferably, the imaging polymer of the invention contains a lactone moiety, more preferably a pendant lactone moiety. Examples of imaging polymers containing lactone moieties are well known in the art. See for example US Published Patent Application No. 20060216643A1, and U.S. Pat. Nos. 7,087,356, 7,063,931, 6,902,874, 6,730,452, 6,627,391, 6,635,401 and 6,756,180. Some preferred lactone-containing monomeric units for inclusion in the imaging polymer are:

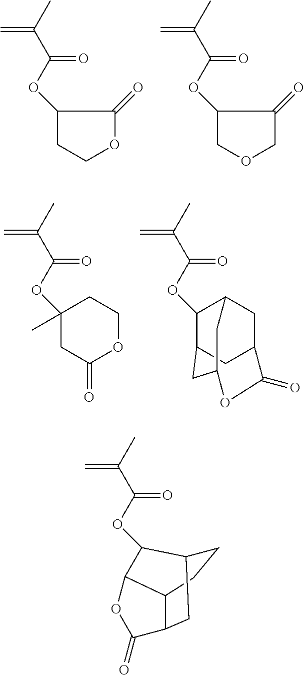 [SMILES: C=C(C)C(=O)OC1CCOC1=O ; C=C(C)C(=O)OC1COCC1=O ; C=C(C)C(=O)OC1(C)CCOC(=O)C1 ; C=C(C)C(=O)OC1C2CC3CC1CC(C2)C(=O)O3 ; C=C(C)C(=O)OC1C2CCC3C(C2)C(=O)OC31]

In one embodiment of these inventive compositions, preferred imaging polymers contain at least about 5 mole % of lactone-containing monomeric units based on the total monomeric units in the imaging polymer, more preferably about 10-50 mole %, most preferably 15-35 mole %.

The imaging polymer may also contain mono- or poly-hydroxy-substituted derivatives of adamantyl methacrylates or acrylates.

### Negative Molecular Glass Photoresist Resins

In another embodiment of these inventive compositions, these can be based on one class of EUV photoresist that have recently been reported is that of negative-tone molecular glass photoresists based on the crosslinking of monomolecular epoxides [C. Popescu; G. O'Callaghan; A. McClelland; J. Roth; T. Lada; T. Kudo; R. Dammel; M. Moinpour; Y. Cao; A. P. G. Robinson, Proc. SPIE 11612, Advances in Patterning Materials and Processes XXXVIII, 116120K (5 Apr. 2021); doi: 10.1117/12.2583888], [Richard A. Lawson, Clifford L. Henderson, Journal of Micro/Nanolithography, MEMS, and MOEMS, Vol. 9, Issue 1, 013016 (January 2010). DOI: 10.1117/1.3358383], [R. A. Lawson, C. T. Lee, C. L. Henderson, R. Whetsell, L. Tolbert, and Y. Wang, J. Vac. Sci. Technol. B, 25 (6), 2140-2144 (2007). DOI 10.1116/1.2801885]. In these resist systems, a strong acid, often hexafluoroantimonic acid generated from a PAG upon exposure, catalyzes the crosslinking of di-, tri-, or higher functional monomolecular epoxides. For EUV exposures, the higher acid yields from the acceptor-substituted PAGs of this invention leads to higher photospeeds for this type of photoresist.

### Acid Quenchers

Suitable acid quenchers include, but are not limited to, a basic material or combination of materials such as an amine compound or a mixture of amine compounds having a boiling point above 100° C., at atmospheric pressure, and a pKₐ of at least 1. Such acid quenchers include, but are not limited to, amine compounds having structures (XIIa), (XIIb), (XIIc), (XIId), (XIIe), (XIIf), (XIIg), (XIIh), (XIIi) (XIIj), (XIIk) and (XIIl) or a mixture of compounds from this group; wherein R_{b1} is C-1 to C-20 saturated alkyl chain or a C-2 to C-20 unsaturated alkyl chain; R_{b2}, R_{b3}, R_{b4}, R_{b5}, R_{b6}, R_{b7}, R_{b8}, R_{b9}, R_{b10}, R_{b11}, R_{b12} and R_{b13} are independently selected from the group of H, and a C-1 to C-20 alkyl as shown below:

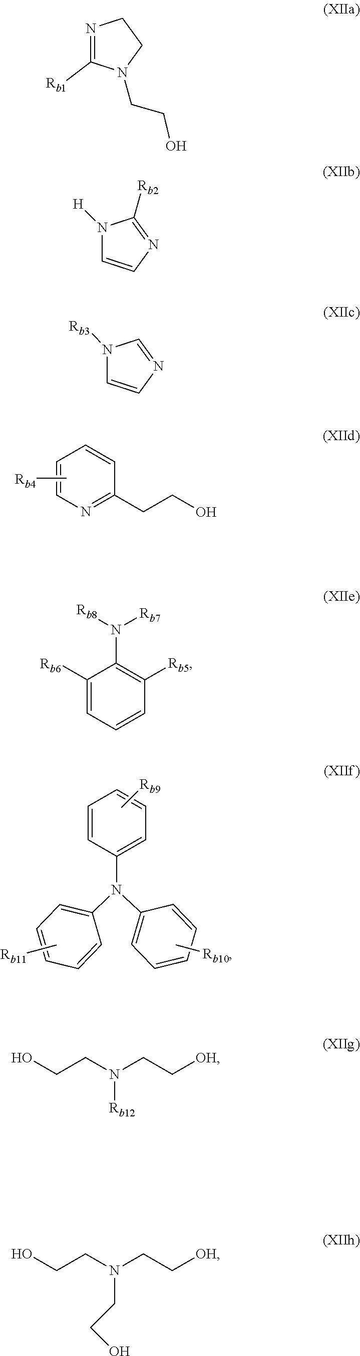

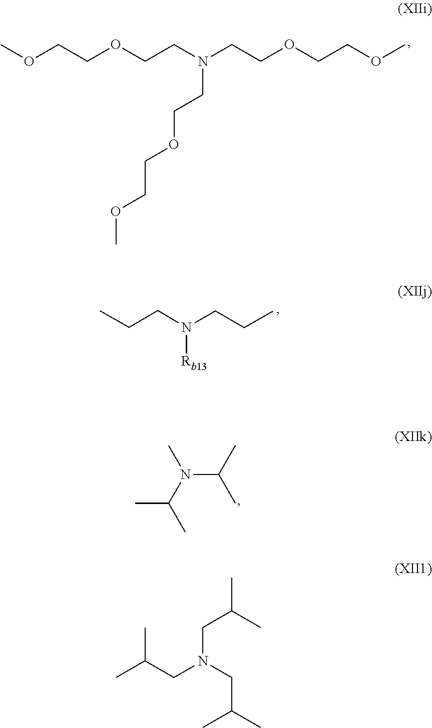

Other suitable acid quenchers are tetraalkylammonium or trialkylammonium salts of carboxylic acid. Specific non limiting examples are mono(tetraalkyl ammonium) of dicarboxylic acid, di(tetraalkyl ammonium) salts of dicarboxylic acid, mono(trialkyl ammonium) of dicarboxylic acid, or di(trialkyl ammonium) salts of dicarboxylic acid. Non-limiting examples of suitable dicarboxylic acid for these salts are oxalic acid, maleic acid, malonic acid, fumaric acid, phthalic acid and the like. Structure (XIIma) to (XIImd) gives a general structure for such materials wherein Rqa to Rqd are independently a C-4 to C-8 alkyl group, Rqe is a valence bond, an arylene moiety, a C-1 to C-4 alkylene moiety, an alkenyl moiety (—C(Rqf)═C(Rqg)-, wherein Rqf and Rqg are independently H or a C-1 to C-4 alkyl). Structure (XIIme) gives a specific example of such a material.

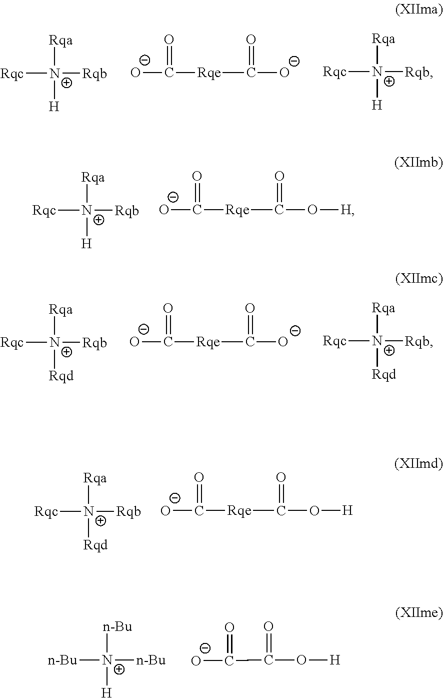

### Organic Spin Coating Solvent

Organic spin coating solvents suitable for dissolving the above-described EUV compositions include a glycol ether derivative such as ethyl cellosolve, methyl cellosolve, propylene glycol monomethyl ether (PGME), diethylene glycol monomethyl ether, diethylene glycol monoethyl ether, dipropylene glycol dimethyl ether, propylene glycol n-propyl ether, or diethylene glycol dimethyl ether; a glycol ether ester derivative such as ethyl cellosolve acetate, methyl cellosolve acetate, or propylene glycol monomethyl ether acetate (PGMEA); carboxylates such as ethyl acetate, n-butyl acetate and amyl acetate; carboxylates of di-basic acids such as diethyloxalate and diethylmalonate; dicarboxylates of glycols such as ethylene glycol diacetate and propylene glycol diacetate; and hydroxy carboxylates such as methyl lactate, ethyl lactate (EL), ethyl glycolate, and ethyl-3-hydroxy propionate; a ketone ester such as methyl pyruvate or ethyl pyruvate; an alkoxycarboxylic acid ester such as methyl 3-methoxypropionate, ethyl 3-ethoxypropionate, ethyl 2-hydroxy-2-methylpropionate, or methylethoxypropionate; a ketone derivative such as methyl ethyl ketone, acetyl acetone, cyclopentanone, cyclohexanone or 2-heptanone; a ketone ether derivative such as diacetone alcohol methyl ether; a ketone alcohol derivative such as acetol or diacetone alcohol; a ketal or acetal like 1,3 dioxolane and diethoxypropane; lactones such as butyrolactone; an amide derivative such as dimethylacetamide or dimethylformamide, anisole, and mixtures thereof. Also, theses solvents may be used as “organic solvent developer” in the some of the processes for using the inventive photoresist in when exposed to e-beam or EUV radiation as described below.

### Optional Crosslinking Components

The EUV and e-beam compositions describe herein intended for negative tone development with an organic solvent may additionally contain as an optional component crosslinkers. These material are multifunctional compounds containing a moiety which under the influence of photogenerated acid form crosslinks in the photoresist film. Examples of such components are multifunctional alkyl and aryl epoxides, which form crosslinking through ring opening of epoxides or N-methoxymethylated melamine crosslinker derivatives, benzyl alcohol derivatives or vinyl cyclic acetal derivatives which form crosslinks through the formation of reactive carbocations (Polymers for Microelectronics ACS Symposium Series ACS, (1993), Chapter 1 Chemically Amplification Mechanisms for Microlithography, E. Reichmanis et al, pages 3) and (Chemical Amplification Resists for Microlithography Adv Polymer Sci, Hiroshi Ito (2005) 172, page 37).

### Other Optional Components

Additionally, the EUV and e-beam compositions described herein, may further comprise additives selected from the group consisting of surfactants, inorganic-containing polymers; additives including small molecules, inorganic-containing molecules, surfactants, other photoacid generators, thermal acid generators, hardeners, cross-linkers, chain extenders, and the like; and combinations comprising at least one of the foregoing.

### Inventive Positive Chemically Amplified Photoresists and Processing

### Positive Chemically Amplified Photoresist Compositions

By using such materials as described herein another aspect of this invention is a positive chemically amplified EUV or e-beam photoresist composition comprising,
1) any one of the inventive compound of structure (I), (Ia), (Ib), and (Ic), as described herein,
2) a photoresist resin as described above which undergoes chemically amplified deprotection catalyzed by photogenerated acid, releasing a resin which is soluble in aqueous base,
3) an optional acid quencher component,
4) an organic spin coating solvent.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

By using such materials as described herein another aspect of this invention is a positive chemically amplified EUV or e-beam photoresist composition comprising,
1a) a compound of structure (I) wherein,
R₁, R₂, R₁ₐ and R₂ₐ are independently selected from H, nitro, cyano, and an alkylsulfonyl, wherein at least two of R₁, R₂, R₁ₐ and R₂ₐ are independently selected from nitro, cyano, and an alkylsulfonyl, and X⁻ is an anion of an acid with a pKₐ lower than 0.

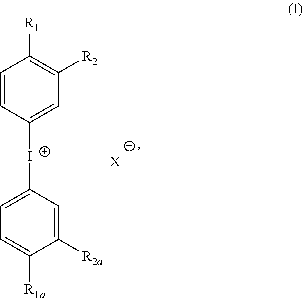

2a) a photoresist resin which undergoes chemically amplified deprotection catalyzed by photogenerated acid, releasing a resin which is soluble in aqueous base,
3a) an optional acid quencher component,
4a) an organic spin coating solvent.
   In yet another aspect of this embodiment the optional acid quencher component is present and may be selected from suitable materials as described herein.
   In yet another aspect of this embodiment the organic spin coating solvent may be selected from any one organic spin coating solvent as described herein or mixture of at least two such solvent.

By using such materials as described herein another aspect of this invention is a positive chemically amplified EUV or e-beam photoresist composition comprising,
1b) a compound of structure (I) wherein,
either R₁ and R₁ₐ, R₂ and R₂ₐ, R₁ₐ and R₂, or R₁ and R₂ₐ are independently selected from nitro, cyano, and alkylsulfonyl, and X⁻ is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate, and X⁻ is an anion of an acid with a pKₐ lower than 0,

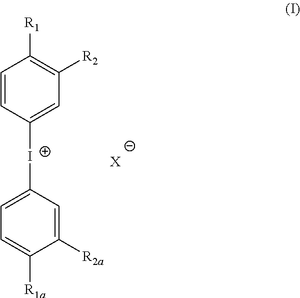

2b) a photoresist resin which undergoes chemically amplified deprotection catalyzed by photogenerated acid, releasing a resin which is soluble in aqueous base,
3b) an optional acid quencher component,
4b) an organic spin coating solvent.
   In other aspects of this embodiments positive photoresist resins as described herein may specifically be employed.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

### Processes Using Positive Chemically Amplified Photoresists

Another aspect of this invention is a process of forming a positive image with a positive chemically amplified photoresist by EUV or e-beam exposure in a substrate, comprising step i) to iv);
i) coating the positive chemically amplified EUV or e-beam photoresist composition of any one of the above described inventive positive chemically amplified photoresist on a substrate forming a coated film,
ii) baking said coated film to form a baked coated film,
iii) exposing regions of the baked coated film through a mask with EUV or e-beam radiation, forming exposed and unexposed regions,
iv) an optional post exposure baking step,
v) developing away the exposed regions with an aqueous base developer forming a positive image pattern in said coated photoresist on the substrate,
vi) etching the substrate with a plasma or a chemical etchant using said positive image pattern as a mask, forming a positive image in the substrate.

In one aspect of this embodiment process step iv) is not optional. In one aspect of this embodiment the aqueous base developer in step v) is 0.26 N TMAH at room temperature.

### Processes Using Positive Chemically Amplified Photoresists to Form Negative Image

Another aspect of this invention is a process of forming a negative image with a positive chemically amplified photoresist by EUV or e-beam exposure in a substrate, comprising step ia) to via);
ia) coating the positive chemically amplified EUV or e-beam photoresist composition of any one of the above described inventive positive chemically amplified photoresist on a substrate forming a coated film,
iia) baking said coated film to form a baked coated film,
iiia) exposing regions of the baked coated film through a mask with EUV or e-beam radiation, forming exposed and unexposed regions,
iva) an optional post exposure baking step,
va) developing away the unexposed regions with an organic solvent developer forming a negative image pattern in said coated photoresist on the substrate,
via) etching the substrate with a plasma or a chemical etchant using said negative image pattern as a mask, forming a negative image in the substrate.

In one aspect of this embodiment process step iva) is not optional. In another aspect of this embodiment organic solvent developer in step va) is n-butyl acetate at room temperature.

### Negative Chemically Amplified Photoresist Compositions

By using such materials as described herein another aspect of this invention is a negative chemically amplified EUV or e-beam photoresist composition comprising,
1c) any one of the inventive compound of structure (I), (Ia), (Ib), and (Ic), as described herein,
2c) a photoresist resin soluble in aqueous base which undergoes chemically amplified crosslinking in the presence of a photogenerated acid,
3c) an optional crosslinking component,
4c) an optional acid quencher component,
5c) an organic spin coating solvent.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

By using such materials as described herein another aspect of this invention is a negative chemically amplified EUV or e-beam photoresist composition comprising,
1d) a compound of structure (I) wherein,
R₁, R₂, R₁ₐ and R₂ₐ are independently selected from H, nitro, cyano, and alkylsulfonyl, wherein at least two of R₁, R₂, R₁ₐ and R₂ₐ are independently selected from nitro, cyano, and alkylsulfonyl, and X⁻ is an anion of an acid with a pKₐ lower than 0.

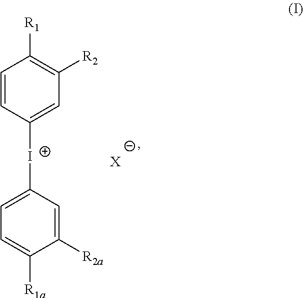

2d) a photoresist resin soluble in aqueous base which undergoes chemically amplified crosslinking in the presence of a photogenerated acid,
3d) an optional crosslinking component,
4d) an optional acid quencher component,
5d) an organic spin coating solvent.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

By using such materials as described herein another aspect of this invention is a negative chemically amplified EUV or e-beam photoresist composition comprising,
1e) a compound of structure (I) wherein,
R₁, R₂, R₁ₐ and R₂ₐ are independently selected from H, nitro, cyano, and alkylsulfonyl, wherein at least two of R₁, R₂, R₁ₐ and R₂ₐ are independently selected from nitro, cyano, and alkylsulfonyl, and X⁻ is an anion of an acid with a pKₐ lower than 0.

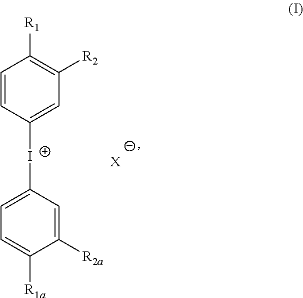

2e) a photoresist resin soluble in aqueous base which undergoes chemically amplified crosslinking in the presence of a photogenerated acid,
3e) a crosslinking component,
4e) an optional acid quencher component,
5e) an organic spin coating solvent.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

By using such materials as described herein another aspect of this invention is a negative chemically amplified EUV or e-beam photoresist composition comprising,
1f) a compound of structure (I) wherein,
either R₁ and R₁ₐ, R₂ and R₂ₐ, R₁ₐ and R₂, or R₁ and R₂ₐ are independently selected from nitro, cyano, and alkylsulfonyl, and X⁻ is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate.

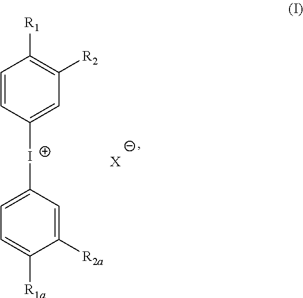

2f) a photoresist resin soluble in aqueous base which undergoes chemically amplified crosslinking in the presence of a photogenerated acid,
3f) an optional crosslinking component,
4f) an optional acid quencher component,
5f) an organic spin coating solvent.

In yet another aspect of this embodiment the optional acid quencher component is present and may be selected from suitable materials as described herein. In yet another aspect of this embodiment the organic spin coating solvent may be selected from any one organic spin coating solvent as described herein or mixture of at least two such solvent.

### Processes Using Negative Chemically Amplified Photoresists

Another aspect of this invention is a process of forming a negative image with a negative chemically amplified photoresist by EUV or e-beam exposure on a substrate, comprising step ib) to vib)
ib) coating the negative chemically amplified EUV photoresist composition of any one of the above describe inventive negative chemically amplified photoresist on a substrate forming a coated film,
iib) baking said coated film to form a baked coated film,
iiib) exposing regions of the baked film through a mask with EUV or e-beam radiation, forming exposed and unexposed regions,
ivb) an optional post exposure baking step,
vb) developing away the unexposed regions either with an aqueous base or organic solvent developer forming a negative image pattern in said coated photoresist on the substrate,
vib) etching the substrate with a plasma or a chemical etchant using said negative image pattern as a mask, forming a negative image in the substrate.

In one embodiment of this process step ivb) is not optional. In one embodiment of this process step in step vb) the developer is an aqueous base; in another aspect of this embodiment the developer is 0.26 N TMAH at room temperature. In another embodiment of this process, in step vb), the developer is an organic solvent; in another aspect of this embodiment the developer is n-butyl acetate at room temperature.

Compositions with Crosslinkable Molecular Glasses

Another aspect of this invention is a negative chemically amplified EUV or e-beam photoresist composition comprising,
1g) a compound of structure (I) wherein,
R₁, R₂, R₁ₐ and R₂ₐ are independently selected from H, nitro, cyano, and an alkylsulfonyl, wherein at least two of R₁, R₂, R₁ₐ and R₂ₐ are independently selected from nitro, cyano, and an alkylsulfonyl, and X⁻ is an anion of an acid with a pKₐ lower than 0,

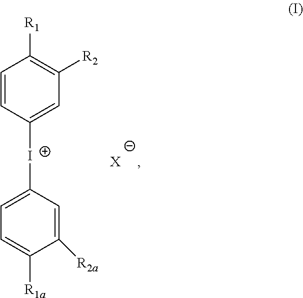

2g) a molecular glass compound comprising from 3 to 5 crosslinking moieties selected from oxiranes, oxetanes or mixtures thereof which undergo crosslinking under the influence of acid formed by irradiation of component 1a),
3g) an optional acid quencher component,
4g) an organic spin coating solvent.

In one aspect of this embodiment said molecular glass compound has structure (II)

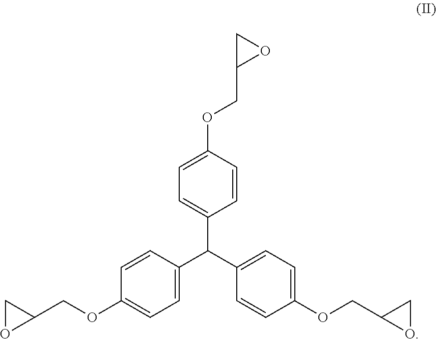 [SMILES: c1cc(C(c2ccc(OCC3CO3)cc2)c2ccc(OCC3CO3)cc2)ccc1OCC1CO1]

### Processes Using Negative Crosslinkable Molecular Glasses

Another aspect of this invention is the process of forming negative image with a negative photoresist by EUV or e beam exposure, comprising step ic) to vic) using said composition described above containing a molecular glass compound
ic) coating the negative chemically amplified EUV photoresist or e-beam composition as described above containing a molecular glass compound on a substrate, to form a coated film,
iic) baking said coated film to form a baked coated film,
iiic) exposing regions of the baked coated film through a mask with EUV or e-beam radiation, forming exposed and unexposed regions,
ivc) an optional post exposure baking step,
vc) developing away the unexposed regions with an organic solvent developer forming a negative image pattern in said coated molecular glass on the substrate,
vic) etching the substrate with a plasma or a chemical etchant using said negative image pattern as a mask, forming a negative image in the substrate.

Additionally, the above described EUV compositions may further comprise additives selected from the group consisting of surfactants, inorganic-containing polymers; additives including small molecules, inorganic-containing molecules, surfactants, other photoacid generators, thermal acid generators, quenchers, hardeners, cross-linkers, chain extenders, and the like; and combinations comprising at least one of the foregoing.

### EXAMPLES

### Chemicals and Characterization

All chemicals unless otherwise indicated were purchased from Sigma Aldrich (3050 Spruce St., St. Louis, MO 63103) of highest commercial grade and used as received unless otherwise specified.

### Characterization Methods

NMR spectra were recorded either on a 400 MHz or a 500 MHz Bruker Advance II+ spectrometer using deuterated solvents from Sigma-Aldrich (Merck). Chemical shifts were reported as d values (ppm) and were calibrated according to internal standard Si(OMe)₄ (0.00 ppm).

TABLE 2
List of Iodonium Salt Synthetic Examples

| Synthetic | | | |
|---|---|---|---|
| Example | | | |
| PAG-# | PAG Cation | PAG Anion | Structure |
| 1 PAG-1 | Bis(4- nitrophenyl)iodonium | tetrafluoroborate | 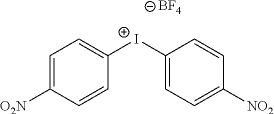 [SMILES: "BF4" ; O=[N+]([O-])c1ccc([I+]c2ccc([N+](=O)[O-])cc2)cc1] |
| 2 PAG-2 | Bis(4- nitrophenyl)iodonium | 4,4,5,5,6,6- hexafluoro-1,3,2- dithiazinan-2-ide 1,1,3,3-tetraoxide | 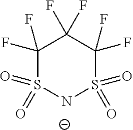 [SMILES: O=S1(=O)NS(=O)(=O)C(F)(F)C(F)(F)C1(F)F] 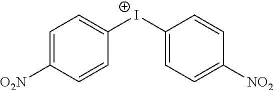 [SMILES: O=[N+]([O-])c1ccc([I+]c2ccc([N+](=O)[O-])cc2)cc1] |
| 3 PAG-3 | Bis(3- nitrophenyl)iodonium | tetrafluoroborate | 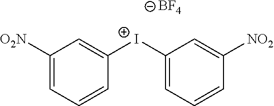 [SMILES: "BF4" ; O=[N+]([O-])c1cccc([I+]c2cccc([N+](=O)[O-])c2)c1] |
| 4 PAG-4 | Bis(3- nitrophenyl)iodonium | 4,4,5,5,6,6- hexafluoro-1,3,2- dithiazinan-2-ide 1,1,3,3-tetraoxide | 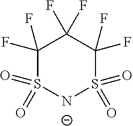 [SMILES: O=S1(=O)[N-]S(=O)(=O)C(F)(F)C(F)(F)C1(F)F] 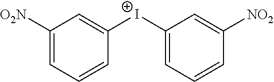 [SMILES: O=[N+]([O-])c1cccc([I+]c2cccc([N+](=O)[O-])c2)c1] |
| 5 PAG-5 | Bis(2- nitrophenyl)iodonium | tetrafluoroborate | 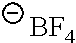 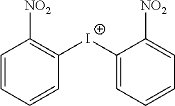 [SMILES: O=[N+]([O-])c1ccccc1[I+]c1ccccc1[N+](=O)[O-]] |
| 6 PAG-6 | Bis(2- nitrophenyl)iodonium | 4,4,5,5,6,6- hexafluoro-1,3,2- dithiazinan-2-ide 1,1,3,3-tetraoxide | 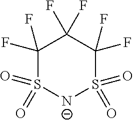 [SMILES: O=S1(=O)[N-]S(=O)(=O)C(F)(F)C(F)(F)C1(F)F] 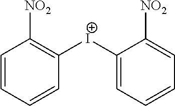 [SMILES: O=[N+]([O-])c1ccccc1[I+]c1ccccc1[N+](=O)[O-]] |
| 7 PAG-7 | (3-nitrophenyl)(4- nitrophenyl)iodonium | tetrafluoroborate | 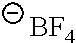 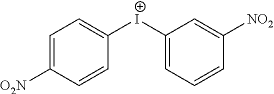 [SMILES: O=[N+]([O-])c1ccc([I+]c2cccc([N+](=O)[O-])c2)cc1] |
| 8 PAG-8 | (3-nitrophenyl)(4- nitrophenyl)iodonium | 4,4,5,5,6,6- hexafluoro-1,3,2- dithiazinan-2-ide 1,1,3,3-tetraoxide | 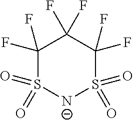 [SMILES: O=S1(=O)[N-]S(=O)(=O)C(F)(F)C(F)(F)C1(F)F] 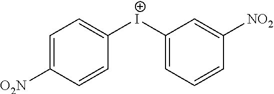 [SMILES: O=[N+]([O-])c1ccc([I+]c2cccc([N+](=O)[O-])c2)cc1] |
| 9 PAG-9 | bis(4- cyanophenyl)iodonium | tetrafluoroborate | 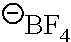 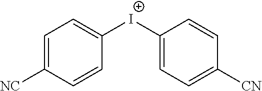 [SMILES: N#Cc1ccc([I+]c2ccc(C#N)cc2)cc1] |
| 10 PAG-10 | bis(4- cyanophenyl)iodonium | 4,4,5,5,6,6- hexafluoro-1,3,2- dithiazinan-2-ide 1,1,3,3-tetraoxide | 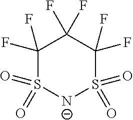 [SMILES: O=S1(=O)[N-]S(=O)(=O)C(F)(F)C(F)(F)C1(F)F] 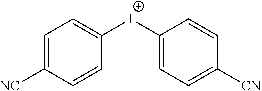 [SMILES: N#Cc1ccc([I+]c2ccc(C#N)cc2)cc1] |
| 11 PAG-11 | bis(2-methyl-5- nitrophenyl)iodonium | bromide | 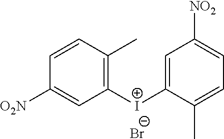 [SMILES: Cc1ccc([N+](=O)[O-])cc1[I+]c1cc([N+](=O)[O-])ccc1C ; [Br-]] |
| 12 PAG-12 | bis(2-methyl-5- nitrophenyl)iodonium | tris(trifluoromethane- sulfonyl) methanide | 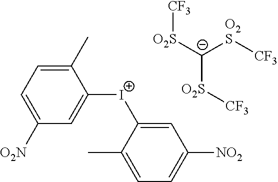 [SMILES: Cc1ccc([N+](=O)[O-])cc1[I+]c1cc([N+](=O)[O-])ccc1C ; O=S(=O)([C-](S(=O)(=O)C(F)(F)F)S(=O)(=O)C(F)(F)F)C(F)(F)F] |
| 13 PAG-13 | bis(3-nitrophenyl) iodonium | bromide | 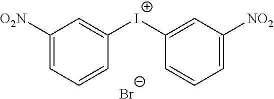 [SMILES: O=[N+]([O-])c1cccc([I+]c2cccc([N+](=O)[O-])c2)c1 ; [Br-]] |
| 14 PAG-14 | bis(3-nitrophenyl) iodonium | tris(trifluoromethane- sulfonyl) methanide | 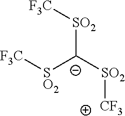 [SMILES: O=S(=O)([C-](S(=O)(=O)C(F)(F)F)S(=O)(=O)C(F)(F)F)C(F)(F)F] 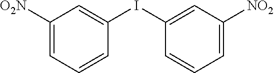 |
| 15* PAG-1 | bis(4- nitrophenyl)iodonium | tetrafluoroborate | 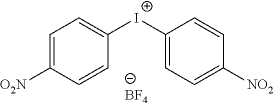 |
| 16 PAG-15 | bis(4- nitrophenyl)iodonium | tris(trifluoromethane- sulfonyl) methanide | 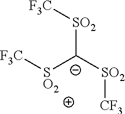 [SMILES: O=S(=O)([C-](S(=O)(=O)C(F)(F)F)S(=O)(=O)C(F)(F)F)C(F)(F)F] 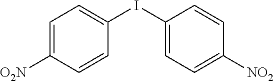 |
| 17** PAG-9 | bis(4- cyanophenyl)iodonium | tetrafluoroborate | 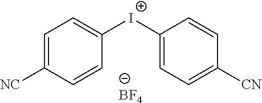 |
| 18 PAG-16 | bis(4- cyanophenyl)iodonium | tris(trifluoromethane- sulfonyl) methanide | 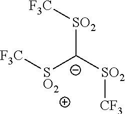 [SMILES: O=S(=O)([C-](S(=O)(=O)C(F)(F)F)S(=O)(=O)C(F)(F)F)C(F)(F)F] 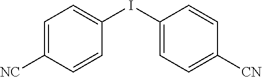 |
| 19*** PAG-10 | bis(4- cyanophenyl)iodonium | 4,4,5,5,6,6- hexafluoro-1,3,2- dithiazinan-2-ide 1,1,3,3-tetraoxide | 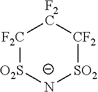 [SMILES: O=S1(=O)[N-]S(=O)(=O)C(F)(F)C(F)(F)C1(F)F] 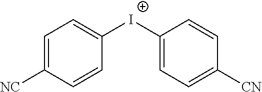 [SMILES: N#Cc1ccc([I+]c2ccc(C#N)cc2)cc1] |
| 20**** PAG-4 | bis(3- nitrophenyl)iodonium | 4,4,5,5,6,6- hexafluoro-1,3,2- dithiazinan-2-ide 1,1,3,3-tetraoxide | 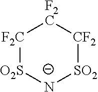 [SMILES: O=S1(=O)[N-]S(=O)(=O)C(F)(F)C(F)(F)C1(F)F] 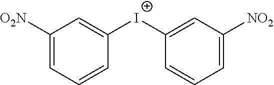 [SMILES: O=[N+]([O-])c1cccc([I+]c2cccc([N+](=O)[O-])c2)c1] |
| 21***** | bis(4- nitrophenyl)iodonium | 4,5,5,6,6-hexafluoro- 1,3,2-dithiazinan-2-ide 1,1,3,3-tetraoxide | 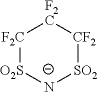 [SMILES: O=S1(=O)[N-]S(=O)(=O)C(F)(F)C(F)(F)C1(F)F] 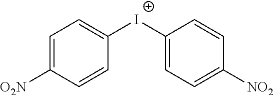 [SMILES: O=[N+]([O-])c1ccc([I+]c2ccc([N+](=O)[O-])cc2)cc1] |

*: alternate synthesis to Example 1;
**: alternate synthesis to Example 9;
***: alternate synthesis to Example 10;
****: alternative synthesis to Example 4;
*****: alternate synthesis to Example 2.

### Synthetic Example 1: Synthesis of bis(4-nitrophenyl)iodonium tetrafluoroborate (PAG-1)

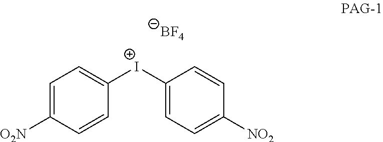 [SMILES: "BF4" ; O=[N+]([O-])c1ccc([I+]c2ccc([N+](=O)[O-])cc2)cc1]

meta-Chloroperoxybenzoic acid (mCPBA, CAS: 937-14-4, 3.8 g, 22 mmol) was dissolved in 100 mL DCM and treated with 1-iodo-4-nitrobenzene (CAS: 636-98-6, 5.1 g, 20 mmol). Boron trifluoride etherate (CAS: 109-63-7, 7.1 g, 50 mmol) was added dropwise and the mixture was stirred at room temperature for 1 h. Subsequently, the mixture was cooled to 0° C., 4-nitrophenylboronic acid (CAS: 24067-17-2, 3.7 g, 22 mmol) added in portions, stirred for 2 h at r. t. and purified using a silica plug. First, impurities were eluted with DCM, followed by DCM/methanol (20:1) to isolate the crude product. The product fractions were concentrated and precipitated with the addition of tert-butyl methyl ether (MTBE). The solid was washed twice with MTBE and then dried in vacuo to obtain bis(4-nitrophenyl)iodonium tetrafluoroborate in 36% yield (3.3 g).

¹H-NMR (500 MHz, DMSO-d6): δ=8.55 (d, J=9.0 Hz, 4H), 8.34 (d, J=9.0, 4H) ppm. ¹³C-NMR (126 MHz, DMSO-d6): δ=150.1, 137.3, 126.9, 123.4, 49.1 ppm. ¹⁹F-NMR (377 MHz, DMSO-d6): δ=−100.0, −146.2, −148.3 ppm.

### Synthetic Example 2: Synthesis of bis(4-nitrophenyl)iodonium 4,4,5,5,6,6-hexafluoro-1,3,2-dithiazinan-2-ide 1,1,3,3-tetraoxide (PAG-2)

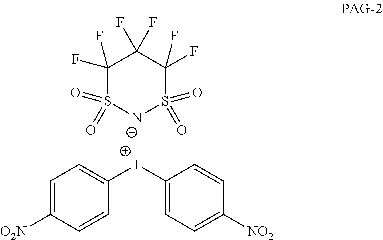 [SMILES: O=S1(=O)[N-]S(=O)(=O)C(F)(F)C(F)(F)C1(F)F ; O=[N+]([O-])c1ccc([I+]c2ccc([N+](=O)[O-])cc2)cc1]

Bis(4-nitrophenyl)iodonium tetrafluoroborate (1 g, 2.1 mmol) was dissolved in 150 mL of ethyl acetate, treated with 1,1,2,2,3,3-hexafluoropropane-1,3-disulfonimide potassium salt (abcr, CAS: 588668-97-7, 0.87 g, 2.6 mmol) and stirred at r. t. for 2 h. The reaction mixture was washed with water (3×100 mL), dried over Na₂SO₄, filtered and reduced under vacuum to obtain 1.2 g (84%) of the product as a white solid.

¹H-NMR (500 MHz, DMSO-d6): δ=8.55 (d, J=9.0 Hz, 4H), 8.34 (d, J=9.0, 4H) ppm.

¹⁹F-NMR (377 MHz, DMSO-d6): δ=−119.5, −125.8 ppm.

### Synthetic Example 3: Synthesis of bis(3-nitrophenyl)iodonium tetrafluoroborate (PAG-3)

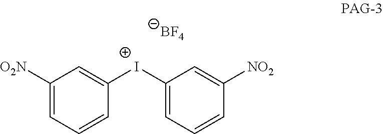 [SMILES: "BF4" ; O=[N+]([O-])c1cccc([I+]c2cccc([N+](=O)[O-])c2)c1]

Following the same procedure as in Synthesis Example 1 using 1-iodo-3-nitrobenzene (CAS: 645-00-1) and 3-nitrophenylboronic acid (CAS: 13331-27-6). Yield: 25% (white solid). ¹H-NMR (500 MHz, DMSO-d6): δ=9.29 (t, J=1.9 Hz, 2H), 8.74 (dt, J=8.1, 1.1 Hz 2H), 8.48 (ddd, J=8.3, 2.3, 0.9 Hz, 2H), 7.85 (t, J=8.1 Hz, 2H) ppm.

### Synthetic Example 4: Synthesis of bis(3-nitrophenyl)iodonium 4,4,5,5,6,6-hexafluoro-1,3,2-dithiazinan-2-ide 1,1,3,3-tetraoxide

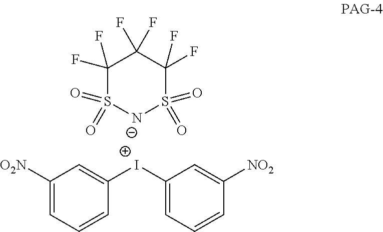 [SMILES: O=S1(=O)[N-]S(=O)(=O)C(F)(F)C(F)(F)C1(F)F ; O=[N+]([O-])c1cccc([I+]c2cccc([N+](=O)[O-])c2)c1]

Following the same procedure as in Synthesis Example 2. Yield: 95% (white solid). ¹H-NMR (500 MHz, DMSO-d6): δ=9.29 (t, J=1.9 Hz, 2H), 8.73 (dt, J=8.0, 1.3 Hz 2H), 8.48 (ddd, J=8.3, 2.3, 0.9 Hz, 2H), 7.85 (t, J=8.1 Hz, 2H) ppm. ¹³C-NMR (126 MHz, DMSO-d6): δ=148.9, 141.8, 133.4, 130.6, 127.5, 117.3 ppm. ¹⁹F-NMR (377 MHz, DMSO-d6): δ=−119.5, −125.8 ppm.

### Synthetic Example 5: Synthesis of bis(2-nitrophenyl)iodonium tetrafluoroborate (PAG-5)

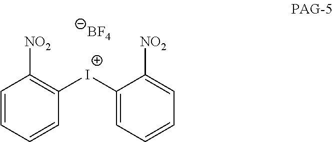 [SMILES: O=[N+]([O-])c1ccccc1[I+]c1ccccc1[N+](=O)[O-] ; "BF4"]

Following the same procedure as in Synthesis Example 1 using 1-iodo-2-nitrobenzene (CAS: 609-73-4) and 2-nitrophenylboronic acid (CAS: 5570-19-4). Yield: 28% (white solid). ¹H-NMR (500 MHz, DMSO-d6): δ=8.55 (dd, J=8.1, 1.6 Hz, 2H), 8.29 (dd, J=8.1, 1.3 Hz 2H), 8.02 (td, J=7.7, 1.3 Hz, 2H), 7.93 (td, J=7.7, 1.6 Hz, 2H) ppm.

### Synthetic Example 6: Synthesis of bis(2-nitrophenyl)iodonium 4,4,5,5,6,6-hexafluoro-1,3,2-dithiazinan-2-ide 1,1,3,3-tetraoxide (PAG-6)

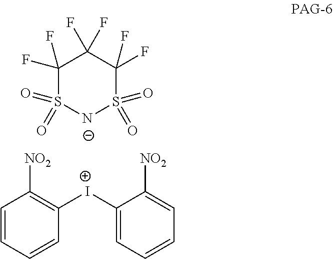 [SMILES: O=S1(=O)[N-]S(=O)(=O)C(F)(F)C(F)(F)C1(F)F ; O=[N+]([O-])c1ccccc1[I+]c1ccccc1[N+](=O)[O-]]

Following the same procedure as in Synthesis Example 2. Yield: 98% (white solid). ¹H-NMR (500 MHz, DMSO-d6): δ=8.55 (dd, J=8.1, 1.5 Hz, 2H), 8.29 (dd, J=7.9, 1.3 Hz 2H), 8.02 (td, J=7.8, 1.2 Hz, 2H), 7.93 (td, J=7.7, 1.6 Hz, 2H) ppm. ¹³C-NMR (126 MHz, DMSO-d6): δ=147.6, 138.0, 134.6, 127.9, 110.1 ppm. ¹⁹F-NMR (377 MHz, DMSO-d6): δ=−119.5, −125.8 ppm.

### Synthetic Example 7: Synthesis of (3-nitrophenyl)(4-nitrophenyl)iodonium tetrafluoroborate PAG-7

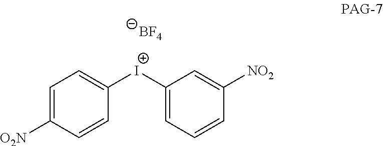 [SMILES: "BF4" ; O=[N+]([O-])c1ccc([I+]c2cccc([N+](=O)[O-])c2)cc1]

Following the same procedure as in Synthesis Example 1 using 1-iodo-4-nitrobenzene (CAS: 636-98-6) and 3-nitrophenylboronic acid (CAS: 13331-27-6). Yield: 29% (white solid). ¹H-NMR (500 MHz, DMSO-d6): δ=9.28 (t, J=2.0 1H), 8.72 (ddd, J=8.0, 1.7, 0.9 Hz 1H), 8.60-8.54 (m, 2H), 8.48 (ddd, J=8.3, 2.3, 0.9 Hz, 1H), 8.37-8.31 (m, 2H), 7.85 (t, J=8.2 Hz, 1H) ppm.

### Synthetic Example 8: Synthesis of (3-nitrophenyl)(4-nitrophenyl)iodonium 4,4,5,5,6,6-hexafluoro-1,3,2-dithiazinan-2-ide 1,1,3,3-tetraoxide PAG-8

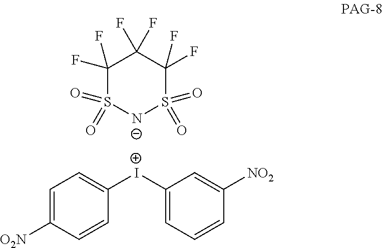 [SMILES: O=S1(=O)[N-]S(=O)(=O)C(F)(F)C(F)(F)C1(F)F ; O=[N+]([O-])c1ccc([I+]c2cccc([N+](=O)[O-])c2)cc1]

Following the same procedure as in Synthesis Example 2. Yield: 99% (white solid). ¹H-NMR (500 MHz, DMSO-d6): δ=9.28 (t, J=1.8 1H), 8.72 (dt, J=8.1, 1.3 Hz 1H), 8.59-8.53 (m, 2H), 8.52-8.44 (m, 1H), 8.36-8.30 (m, 2H), 7.85 (td, J=8.2, 1.1 Hz, 1H) ppm. ¹³C-NMR (126 MHz, DMSO-d6): δ=150.0, 149.0, 141.9, 137.2, 133.4, 130.7, 127.6, 126.9, 123.6, 117.2 ppm. ¹⁹F-NMR (377 MHz, DMSO-d6): δ=−119.5, −125.8 ppm.

### Synthetic Example 9: Synthesis of bis(4-cyanophenyl)iodonium tetrafluoroborate (PAG-9)

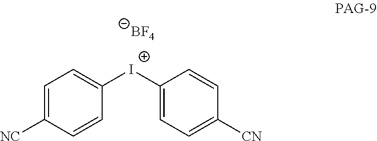 [SMILES: "BF4" ; N#Cc1ccc([I+]c2ccc(C#N)cc2)cc1]

Following the same procedure as in Synthesis Example 1 using 4-iodobenzonitrile (CAS: 3058-39-7) and (4-cyanophenyl)boronic acid (CAS: 126747-14-6). Yield: 30% (white solid). ¹H-NMR (500 MHz, DMSO-d6): δ=8.50-8.44 (m, 4H), 8.07-8.01 (m, 4H) ppm.

### Synthetic Example 10: Synthesis of bis(4-cyanophenyl)iodonium 4,4,5,5,6,6-hexafluoro-1,3,2-dithiazinan-2-ide 1,1,3,3-tetraoxide

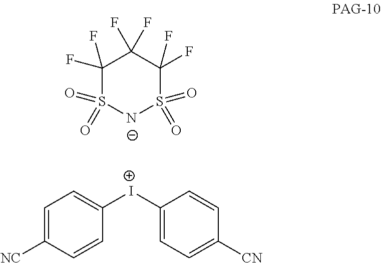 [SMILES: O=S1(=O)[N-]S(=O)(=O)C(F)(F)C(F)(F)C1(F)F ; N#Cc1ccc([I+]c2ccc(C#N)cc2)cc1]

Following the same procedure as in Synthesis Example 2. Yield: 99% (white solid). ¹H-NMR (500 MHz, DMSO-d6): δ=8.50-8.45 (m, 4H), 8.07-7.97 (m, 4H) ppm. ¹³C-NMR (126 MHz, DMSO-d6): δ=136.5, 135.7, 122.0, 117.9, 115.5 ppm. ¹⁹F-NMR (377 MHz, DMSO-d6): δ=−119.5, −125.8 ppm.

### Synthesis Example 11: Synthesis of bis(2-methyl-5-nitrophenyl)iodonium bromide (PAG-11) (Scheme 1)

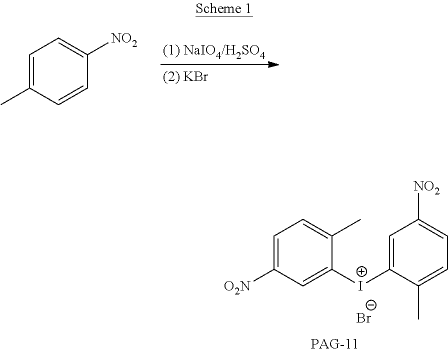

4-nitrotoluene (7.70 g, 55.6 mmole, 2.6 equiv; 30% excess) was dissolved 30 ml of concentrated sulfuric acid (98%) and the stirred mixture was slowly warmed up to 55° C. Sodium metaperiodate (4.62 g, 21.4 mmole, 1.0 equiv) was added portion-wise over 2-hour period, with stirring and keeping the given temperature. The stirring was continued for additional 2 hours while keeping temperature generally at 55° C., and then cooled down to room temperature. The reactions were quenched by pouring the cooled final reaction mixtures into crushed ice in a beaker (400 ml). Any precipitates were filtered off and rejected, the cold filtrates were extracted three times with diethyl ether to remove the unreacted 4-nitrotoluene (3×125 ml, the ethereal extracts were discarded). To the remaining aqueous solutions, potassium bromide salt (6.36 g, in excess) was added with stirring. The precipitated bis(2-methyl-5-nitrophenyl)iodonium bromides (C-1), sparingly soluble in water, were collected by filtration, washed well with cold water until the filtrates were neutral, and air-dried in the dark to obtain the light yellow powder (7.85 g, yield 76.6%); mp=159° C. (decomposed); ¹H NMR (400 MHz, DMSO) δ=9.37, 8.36, 8.35, 7.84, 7.82, 2.74; ¹³C NMR (101 MHz, DMSO) δ=148.78, 146.54, 132.26, 131.93, 127.25, 120.79, 25.29.

### Synthesis Example 12: Synthesis of bis(2-methyl-5-nitrophenyl)iodonium tris(trifluoromethanesulfonyl)methanide (PAG-12) (Scheme 2)

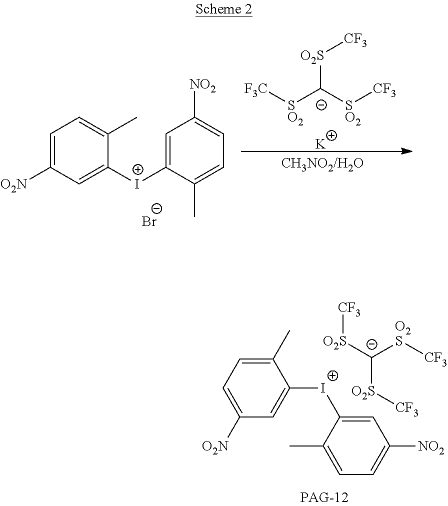 [SMILES: Cc1ccc([N+](=O)[O-])cc1[I+]c1cc([N+](=O)[O-])ccc1C ; O=S(=O)([C-](S(=O)(=O)C(F)(F)F)S(=O)(=O)C(F)(F)F)C(F)(F)F ; [K+] ; [Br-] ; Cc1ccc([N+](=O)[O-])cc1[I+]c1cc([N+](=O)[O-])ccc1C ; O=S(=O)([C-](S(=O)(=O)C(F)(F)F)S(=O)(=O)C(F)(F)F)C(F)(F)F]

The compound obtained in Example 11 (6.03 g, 12.6 mmol, 1.0 equiv) was added to 400 mL of nitromethane, and 100 mL of water, 6.23 g (13.8 mmol, 1.1 equiv) of potassium tris(trifluoromethanesulfonyl) methanide was added thereto, and the mixture was stirred at room temperature for overnight. Then, water was separated, and organic solution was dried by sodium sulfate anhydrous. Finally, nitromethane was stripped off under vacuum at 50° C. to get the target product bis(2-methyl-5-nitrophenyl) iodonium tris(trifluoromethanesulfonyl)methanide (8.11 g, yield 79.5%); mp=165° C.; ¹H NMR (400 MHz, MeOD) δ=9.27, 9.26, 8.44, 8.42, 7.84, 7.82, 2.81; ¹⁹F NMR (377 MHz, MeOD) δ=−78.22; ¹³C NMR (101 MHz, MeOD) δ=149.99, 148.27, 133.79, 133.02, 128.77, 126.17, 122.94, 119.69, 119.46, 116.46, 83.83, 25.81.

### Synthesis Example 13: Synthesis of bis(3-nitrophenyl)iodonium bromide) (PAG-13) (Scheme

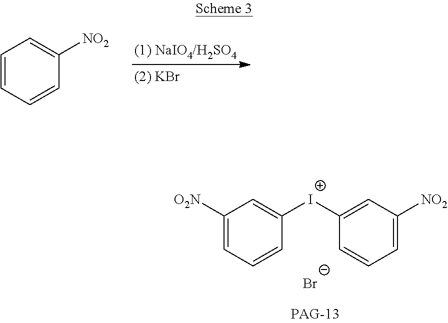 [SMILES: O=[N+]([O-])c1ccccc1 ; O=[N+]([O-])c1cccc([I+]c2cccc([N+](=O)[O-])c2)c1 ; [Br-]]

Nitrobenzene (14.20 g, 115.3 mmole, 2.6 equiv; 30% excess) was dissolved 60 ml of concentrated sulfuric acid (98%) and the stirred mixture was slowly warmed up to 55° C. Sodium metaperiodate (9.59 g, 44.4 mmole, 1 equiv) was added portion-wise over 2 hours, with stirring and keeping the given temperature. The stirring was continued for additional hours while keeping temperature at 55° C., and then cooled down to room temperature. The reactions were quenched by pouring the cooled final reaction mixtures into smushed ice pile in a beaker (600 ml). Any precipitates were filtered off and rejected, the cold filtrates were extracted three times with diethyl ether to remove the unreacted nitrobenzene (3×150 ml, the ethereal extracts were discarded). To the remaining aqueous solutions, potassium bromide salt (13.2 g, in excess) was added with stirring. The precipitated bis(3-nitrophenyl)iodonium bromides (C-2), were collected by filtration, washed well with cold water until the filtrates were neutral, and air-dried in the dark to obtain the light yellow powder (15.82 g, yield 79.1%); ¹H NMR (400 MHz, DMSO) δ=9.21, 8.68, 8.66, 8.41, 8.38, 7.78, 7.76, 7.74; ¹³C NMR (101 MHz, DMSO) δ=148.59, 141.42, 132.81, 130.20, 126.72, 120.15.

### Synthesis Example 14: Synthesis of bis(3-nitrophenyl)iodonium tris(trifluoromethanesulfonyl)methanide (PAG-14) (Scheme 4)

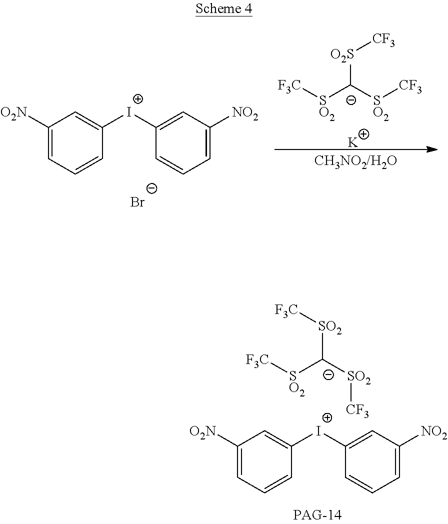 [SMILES: O=S(=O)([C-](S(=O)(=O)C(F)(F)F)S(=O)(=O)C(F)(F)F)C(F)(F)F ; O=[N+]([O-])c1cccc([I+]c2cccc([N+](=O)[O-])c2)c1 ; [K+] ; [Br-] ; O=S(=O)([C-](S(=O)(=O)C(F)(F)F)S(=O)(=O)C(F)(F)F)C(F)(F)F ; O=[N+]([O-])c1cccc([I+]c2cccc([N+](=O)[O-])c2)c1]

The compound obtained in Synthesis Example 13 (5.30 g, 11.8 mmol, 1.0 equiv) was added to 400 mL of nitromethane, and 100 mL of water, 6.35 g (14.1 mmol, 1.2 equiv) of potassium tris(trifluoromethanesulfonyl) methanide was added thereto, and the mixture was stirred at room temperature for overnight. Then, water was separated, and organic solution was dried by sodium sulfate anhydrous. Finally, nitromethane was stripped off under vacuum at 50° C. to get the target product bis(3-nitrophenyl) iodonium tris(trifluoromethanesulfonyl)methanide as (8.23 g, yield 89.5%); mp=205° C. (decomposed); ¹H NMR (400 MHz, MeOD) δ=9.20, 8.63, 8.61, 8.54, 8.52, 7.83, 7.81, 7.79; ¹⁹F NMR (377 MHz, MeOD) δ=−78.14; ¹³C NMR (101 MHz, MeOD) δ=140.99, 132.70, 124.73, 122.01, 119.11, 116.87, 113.63, 110.40, 107.16, 106.39.

### Synthesis Example 15: Synthesis of bis(4-nitrophenyl)iodonium tetrafluoroborate (Alternate Synthesis PAG-1) (Scheme 5)

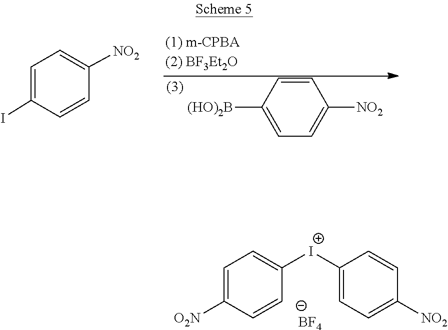

In a 400 mL EasyMax auto reactor, meta-chloroperoxybenzoic acid (m-CPBA) >70%, (16.95 g, 68.8 mmol, 1.1 equiv) was dissolved in 200 mL dichloromethane, followed by addition of 1-iodo-4-nitrobenzene (15.89 g, 62.52 mmol, 1.0 equiv), the solution turned red. After stirring at room temperature for 30 minutes, boron trifluoride etherate, BF₃·Et₂O (20.7 mL, 23.81 g, 164.4 mmol, 2.6 equiv.) was added to the reaction mixture using a syringe, some precipitate was formed inside of the reactor glass wall. The solution was then stirred vigorously for 2 hours and then cooled to 0° C. for approximately 30 minutes. 4-nitrobenzeneboronic acid (12.08 g, 68.8 mmol, 1.1 equiv.) was added to the cold reaction mixture was stirring at 0° C. for 6 hours, then equilibrated to room temperature for overnight. The crude mixture was filtered out and the crude product was washed thrice with dichloromethane and five times with diethyl ether, until TLC tests showed no traces of reactants. The product was filtered out and dried with flow air inside a fuming hood for two days, and a grey powder bis(4-nitrophenyl)iodonium tetrafluoroborate was obtained (13.94 g, yield 48.7%); mp=134° C.; ¹H NMR (400 MHz, DMSO) δ=8.56, 8.54, 8.34, 8.32; ¹⁹F NMR (377 MHz, DMSO) δ=−148.17; ¹³C NMR (101 MHz, DMSO) δ=149.72, 136.69, 126.58, 123.16.

### Synthesis Example 16: Synthesis of bis(4-nitrophenyl)iodonium tris(trifluoromethane-sulfonyl)methanide (PAG-15) (Scheme 6)

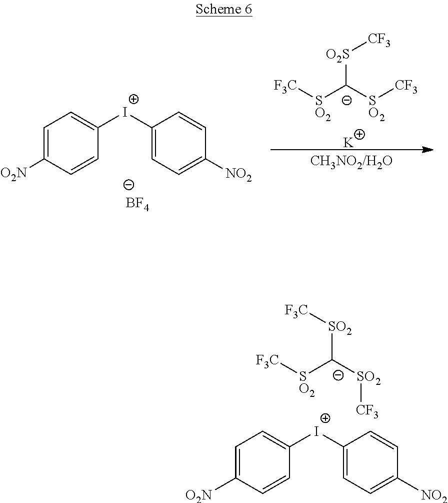

The compound obtained in Synthesis Example 15 (8.01 g, 17.5 mmol, 1.0 equiv) was added to 400 mL of nitromethane, and 100 mL of water, 9.45 g (21.0 mmol, 1.2 equiv) of potassium tris(trifluoromethanesulfonyl) methanide was added thereto, and the mixture was stirred at room temperature for overnight. Then, water was separated, and organic solution was dried by sodium sulfate anhydrous. Finally, nitromethane was stripped off under vacuum at 50° C. to get the target product bis(4-nitrophenyl) iodonium tris(trifluoromethanesulfonyl)methanide (9.51 g, yield 69.5%); mp=205° C. (decomposed); ¹H NMR (400 MHz, MeOD) δ=8.48, 8.46, 8.35, 8.32; ¹⁹F NMR (377 MHz, MeOD) δ=−78.21; ¹³C NMR (101 MHz, MeOD) δ=151.68, 138.05, 127.71, 126.38, 123.14, 121.91, 119.90, 116.66, 84.16.

### Synthesis Example 17: Synthesis of bis(4-cyanophenyl)iodonium tetrafluoroborate (Alternate Synthesis PAG-9 Scheme 7)

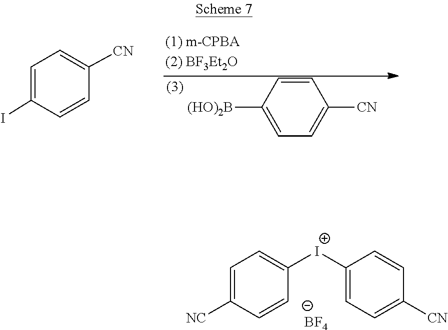

In a 140 mL EasyMax auto reactor, meta-chloroperoxybenzoic acid (m-CPBA) >70%, (12.99 g, 52.69 mmol, 1.1 equiv) was dissolved in 100 mL dichloromethane, followed by addition of 4-iodobenzonitrile (11.31 g, 47.90 mmol, 1.0 equiv.), whereupon the solution turned red. After stirring at room temperature for 30 minutes, boron trifluoride etherate, BF3·Et2O (15.9 mL, 18.25 g, 125.98 mmol, 2.63 equiv.) was added to the reaction mixture using a syringe, some precipitate was formed inside of the reactor glass wall. The solution was then stirred vigorously for 2 hours and then cooled to 0° C. for approximately 30 minutes. (4-cyanophenyl)boronic acid (8.15 g, 52.69 mmol, 1.1 equiv) was added to the cold reaction mixture and was stirring at 0° C. for 6 hours, then equilibrated to room temperature overnight. The crude mixture was filtered out and the crude product was washed thrice with dichloromethane and five times with diethyl ether, until TLC tests showed no traces of reactants. The final product was dried with flowing air inside a fume hood for two days, and bis(4-cyanophenyl)iodonium tetrafluoroborate was obtained as a grey powder (7.02 g, yield 35.1%); ¹H NMR (400 MHz, MeOD) δ=8.42, 8.40, 7.90, 7.88; ¹⁹F NMR (377 MHz, MeOD) δ=−153.33.

### Synthesis Example 18: Synthesis of bis(4-cyanophenyl)iodonium tris(trifluoromethanesulfonyl)methanide (PAG-16) (Scheme 8)

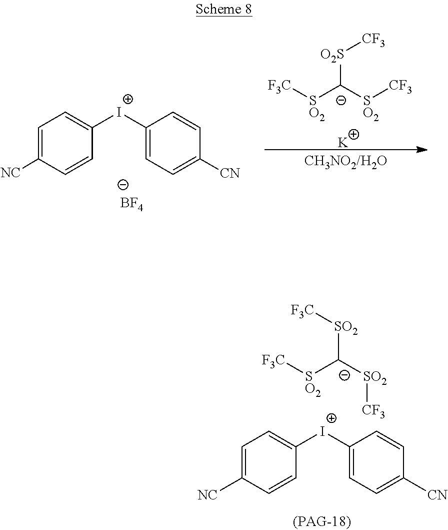

The compound obtained ion Synthesis Example 17 (3.55 g, 8.5 mmol, 1.0 equiv.) was added to 100 mL of nitromethane, and 25 mL of water, 4.21 g (9.3 mmol, 1.1 equiv) of potassium tris(trifluoromethanesulfonyl) methanide was added thereto, and the mixture was stirred at room temperature for overnight. Then, water was separated, and organic solution was dried by anhydrous sodium sulfate. Finally, nitromethane was stripped off under vacuum at 50° C. to get the target product bis(4-cyanophenyl) iodonium tris(trifluoromethanesulfonyl)methanide (6.23 g, yield 98.8%); mp=166° C.; ¹H NMR (400 MHz, MeOD) δ=8.37, 8.35, 7.88, 7.86; ¹⁹F NMR (377 MHz, MeOD) δ=−78.04; ¹³C NMR (101 MHz, MeOD) δ=137.37, 136.39, 126.32, 123.08, 120.28, 119.84, 117.86, 117.72, 116.60, 84.04.

### Synthesis Example 19: Synthesis of bis(4-cyanophenyl)iodonium 4,4,5,5,6,6-hexafluoro-1,3,2-dithiazinan-2-ide 1,1,3,3-tetraoxide (Alternate Synthesis PAG-10) (Scheme 9)

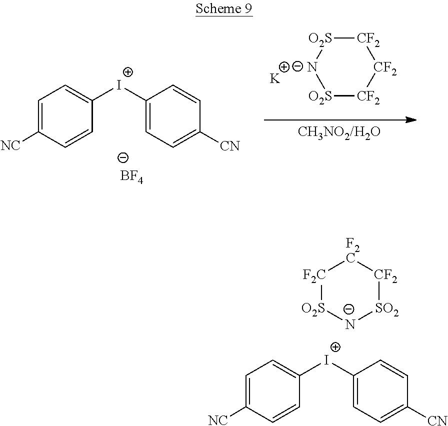

The compound obtained in Synthesis Example 18 (3.54 g, 8.47 mmol, 1.00 equiv) was added to 100 mL of nitromethane, and 25 mL of water, 3.15 g (9.52 mmol, 1.12 equiv) of potassium cyclohexafluoropropane-1,3-bis(sulfonyl)imide was added thereto, and the mixture was stirred at room temperature for overnight. Then, water was separated, and organic solution was dried by sodium sulfate anhydrous. Finally, nitromethane was stripped off under vacuum at 50° C. to get the target product bis(4-cyanophenyl) iodonium cyclohexafluoropropane-1,3-bis(sulfonyl)imide (4.20 g, yield 79.6%); mp=220° C.; ¹H NMR (400 MHz, DMSO) δ=8.44, 8.42, 7.98, 7.96; ¹⁹F NMR (377 MHz,) δ=−119.61, −125.81; ¹³C NMR (101 MHz, DMSO) δ=136.31, 135.36, 121.62, 117.60, 115.65, 115.30, 112.69, 109.57, 106.86.

### Synthesis Example 20 Synthesis of bis(3-nitrophenyl)iodonium 4,4,5,5,6,6-hexafluoro-1,3,2-dithiazinan-2-ide 1,1,3,3-tetraoxide (Alternate Synthesis PAG-4) (Scheme 10)

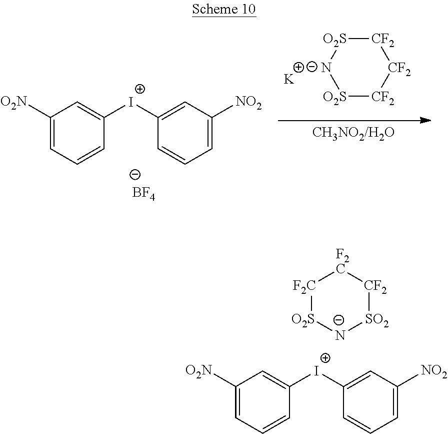

The compound obtained in Synthesis Example 14 (5.00 g, 11.09 mmol, 1.00 equiv) was added to 400 mL of nitromethane, and 100 mL of water, 4.13 g (9.52 mmol, 1.12 equiv) of potassium cyclohexafluoro-propane-1,3-bis(sulfonyl)imide was added thereto, and the mixture was stirred at room temperature for overnight. Then, water was separated, and organic solution was dried by anhydrous sodium sulfate. Finally, nitromethane was stripped off under vacuum at 50° C. to get the target product bis(3-nitrophenyl) iodonium cyclohexafluoropropane-1,3-bis(sulfonyl)imide as (7.25 g, yield 98.6%); mp=175° C.; ¹H NMR (400 MHz, MeOD) δ=9.20, 8.65, 8.63, 8.53, 8.50, 7.83, 7.81, 7.79; ¹⁹F NMR (377 MHz, MeOD) δ=−120.99, −127.50; ¹³C NMR (101 MHz, MeOD) δ=150.41, 142.29, 134.21, 131.52, 128.55, 117.16, 115.74, 114.22, 110.93, 108.21.

### Synthesis Example 21: Synthesis of bis(4-nitrophenyl)iodonium 4,4,5,5,6,6-hexafluoro-1,3,2-dithiazinan-2-ide 1,1,3,3-tetraoxide (Alternate synthesis Example 2) (Scheme 11)

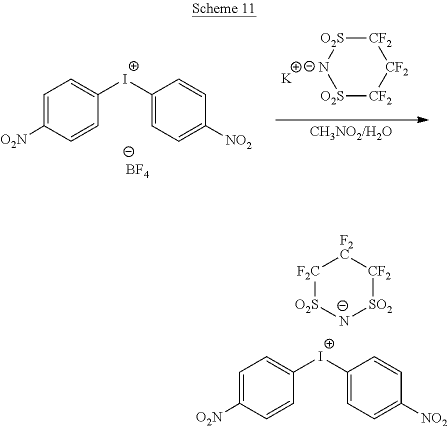

The obtained compound C-3 (3.80 g, 8.30 mmol, 1.00 equiv) was added to 200 mL of nitromethane, and 50 mL of water, 3.09 g (9.33 mmol, 1.12 equiv) of potassium cyclohexafluoro-propane-1,3-bis(sulfonyl)imide was added thereto, and the mixture was stirred at room temperature for overnight. Then, water was separated, and organic solution was dried by sodium sulfate anhydrous. Finally, nitromethane was stripped off under vacuum at 50° C. to get the target product bis(4-nitrophenyl) iodonium cyclohexafluoropropane-1,3-bis(sulfonyl)imide (4.40 g, yield 79.9%); mp=231° C.; ¹H NMR (400 MHz, DMSO) δ=8.56, 8.54, 8.33, 8.31; ¹⁹F NMR (377 MHz, DMSO) δ=−119.55, −125.84; ¹³C NMR (101 MHz, DMSO) δ=149.65, 136.86, 126.48, 123.05, 115.45, 112.48, 109.39, 106.67.

### Lithographic Example 1: E-Beam Contrast Curves for Negative-Tone Molecular Glass Resist

The PAGs of Synthetic Examples 1, 8, and 10 as well as the parent iodonium salt diphenyl iodonium 4,4,5,5,6,6-hexafluoro-1,3,2-dithiazinan-2-ide 1,1,3,3-tetraoxide (prepared from diphenyliodonium tetrafluoroborate analogously to Synthetic Example 2) were formulated into a photoresist with the trifunctional epoxide 2,2′,2″-[methylidynetris(4,1-phenyleneoxymethylene)]tris[oxirane](II) (prepared as described in the literature, Shou Zhao, Xiangning Huang, Andrew J. Whelton, and Mahdi M. Abu-Omar, ACS Sustainable Chem. Eng. 2018, 6, 7600-7608; DOI: 10.1021/acssuschemeng.8b00443).

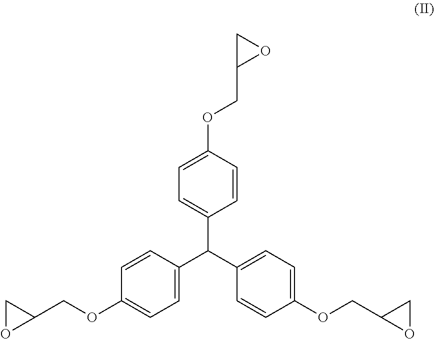 [SMILES: c1cc(C(c2ccc(OCC3CO3)cc2)c2ccc(OCC3CO3)cc2)ccc1OCC1CO1]

### 2,2′,2″-[methylidynetris(4,1-phenyleneoxymethylene)]tris[oxirane]

4 g of the epoxide was dissolved in 100 ml of ethyl lactate. 0.0536 g of PAG were dissolved in 4 ml of ethyl lactate and mixed with the epoxide solution, then stirred for a minimum of 2 hours. The solution was then filtered through a 20 nm PTFE syringe filter to obtain the resist formulation. 3 ml of the resist formulation were deposited on 4″ silicon wafers and spun at 1,000 rpm using a Suss Microtech spin coater to obtain films of approximately 30 nm thickness after a softbake of 75° C. for 300 sec. Initial film thickness was determined on a DECTAC profilometer after scratching the photoresist film. The wafers were exposed on a Tescan SEM MIRA with an acceleration voltage of 20 keV and beam intensity setting of 8. The exposed films were developed by immersion into n-butyl acetate for 3 min and dried using a nitrogen stream. The remaining film thickness in areas exposed to different doses were measured using the same profilometer and contrast curves determined. The doses for 50% film retention (E_{1/2}) were as follows (Table 3). This Table shows that the inventive PAG with specific electron withdrawing substitution show unexpected sensitivity to e-beam and consequently would also show unexpected sensitivity to EUV exposure because in both cases acid formation from PAG proceeds by electron capture and both EUV and e-beam generate secondary electrons capable of such capture:

TABLE 3

| Iodonium derivative | E_{1/2} [μC/cm²] |
|---|---|
| 4,4′-dinitro | 17.8 |
| 3,4′-dinitro | 41.7 |
| 4,4′-dicyano | 59.9 |
| parent | 86.1 |

### Lithographic Example 2: E-Beam Contrast Curves for Positive Tone Chemically Amplified Resist

To 5 g of a 50% w/w solids PGME solution of a ternary copolymer of hydroxystyrene, styrene, and t-butyl acrylate having a molecular weight of approximately 10,000 Dalton, where the monomers are in the ratio of 6:2:2, were added 130.8 mmole of PAG (cyclohexafluoro-propane-1,3-bis(sulfonyl)imide salt of the iodonium cation as described in Table 4) and 0.39 g of a solution of 0.1 N triethanolamine in PGMEA. This solution was diluted with PGMEA to bring the total concentration to 9.12% w/w solids (˜28.3 g PGMEA). The bottles containing the solution were put on rollers overnight and the solution was then filtered through a 20 nm PTFE syringe filter to obtain the resist formulation. 3 ml of the resist formulation were deposited on 4″ silicon wafers and spun at 1,000 rpm using a Suss Microtech spin coater to obtain films with thickness 346 nm to 388 nm after a softbake of 110° C. for 90 sec. Initial film thickness was determined on a DECTAC profilometer after scratching the photoresist film. The wafers were exposed on a Tescan SEM MIRA with an acceleration voltage of 20 keV and beam intensity setting of 8. After exposure, the wafers were baked for 90 sec at a temperature of 130 C. The baked films were developed by immersion into 2.38% w/w TMAH solution, rinsed with water, and dried using a nitrogen stream. The remaining film thickness in areas exposed to different doses were measured using the same profilometer and contrast curves determined. The open point doses E₀ were as follows (Table 4):

TABLE 4

| Iodonium derivative | E₀ [μC/cm²] |
|---|---|
| 4,4′-dinitro | 4 |
| 3,4′-dinitro | 7 |
| 4,4′-dicyano | 3 |
| 2,2′-dinitro | 5 |

The above results indicated that the inventive PAGs impart unexpected sensitivity to positive tone chemically amplified photoresists in e-beam and by extension EUV.

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter.

What is claimed is:

1.-41. (canceled)

42. A positive chemically amplified EUV or e-beam photoresist composition comprising,
1) a compound selected from the group consisting of 1-1), 1-2), 1-3), and 1-4):
1-1) a compound of structure (I), wherein
R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,
1-2) a compound of structure (Ia) wherein,
R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-3) a compound of structure (Ib) wherein,
R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-4) a compound of structure (Ic) wherein,
R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate. 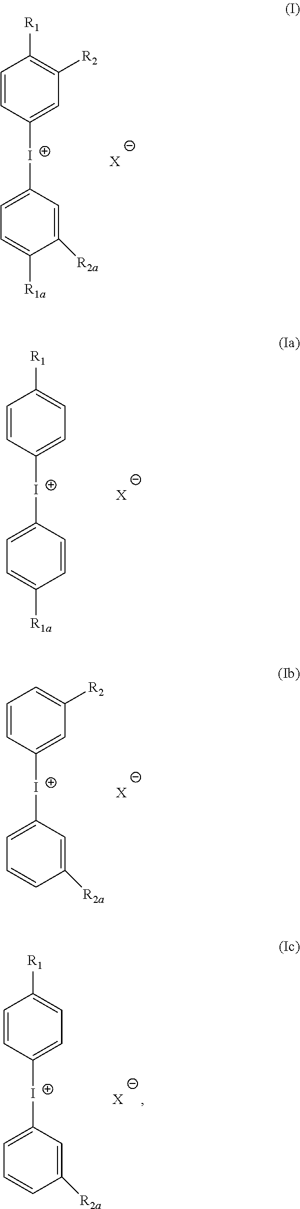
2) a photoresist resin which undergoes chemically amplified deprotection catalyzed by photogenerated acid, releasing a resin which is soluble in aqueous base,
3) an optional acid quencher component,
4) an organic spin coating solvent.

43. The positive chemically amplified EUV or e-beam photoresist composition of claim 42 wherein 1) is a compound a compound of structure (I), wherein R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,

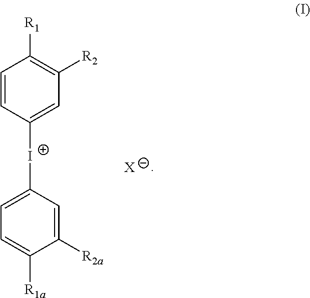

44. The positive chemically amplified EUV or e-beam photoresist composition of claim 42 wherein 1) is a compound of structure (Ia) wherein, R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

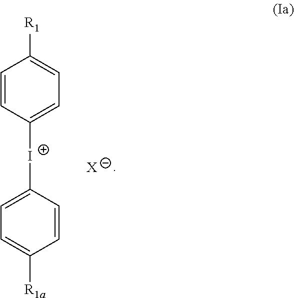

45. A process of forming a positive image with a positive chemically amplified photoresist by EUV or e-beam exposure, comprising step i) to iv);
i) coating the positive chemically amplified EUV or e-beam photoresist composition of claim 42 on a substrate, forming a coated film,
ii) baking said coated film to form a baked coated film,
iii) exposing regions of the baked coated film through a mask with EUV or e-beam radiation, forming exposed and unexposed regions,
iv) an optional post exposure baking step,
v) developing away the exposed regions with an aqueous base developer forming a positive image pattern in said coated photoresist on the substrate,
vi) etching the substrate with a plasma or a chemical etchant using said positive image pattern as a mask, forming a positive image in the substrate.

46. A process of forming a negative image with a positive chemically amplified photoresist by EUV or e-beam exposure, comprising step ia) to via);
ia) coating the positive chemically amplified EUV or e-beam photoresist composition of of claim 42 on a substrate, forming a coated film,
iia) baking said coated film to form a baked coated film,
iiia) exposing regions of the baked coated film through a mask with EUV or e-beam radiation, forming exposed and unexposed regions,
iva) an optional post exposure baking step,
va) developing away the unexposed regions with an organic solvent developer forming a negative image pattern in said coated photoresist on the substrate,
via) etching the substrate with a plasma or a chemical etchant using said negative image pattern as a mask, forming a negative image in the substrate.

47. A negative chemically amplified EUV or e-beam photoresist composition comprising,
1c) a compound selected from the group consisting of 1-1), 1-2), 1-3), and 1-4):
1-1) a compound of structure (I), wherein
R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,
1-2) a compound of structure (Ia) wherein,
R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-3) a compound of structure (Ib) wherein,
R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-4) a compound of structure (Ic) wherein,
R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate. 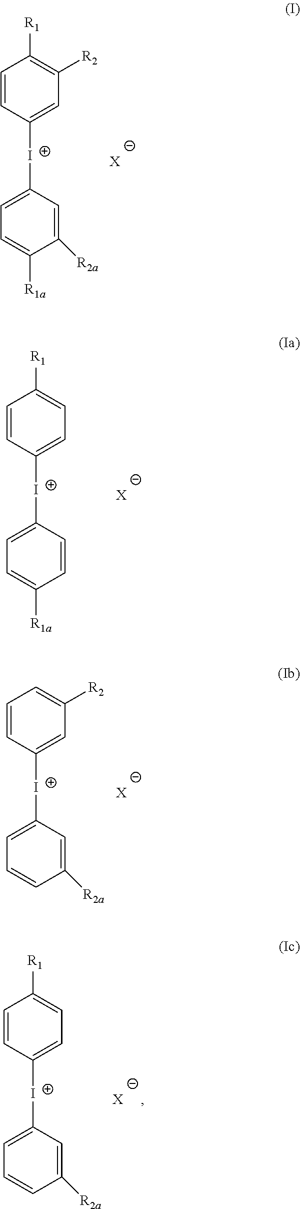
2c) a photoresist resin soluble in aqueous base which undergoes chemically amplified crosslinking in the presence of a photogenerated acid,
3c) an optional crosslinking component,
4c) an optional acid quencher component,
5c) an organic spin coating solvent.

48. The negative chemically amplified EUV or e-beam photoresist composition of claim 47 wherein 1c) is a compound a compound of structure (I), wherein R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,

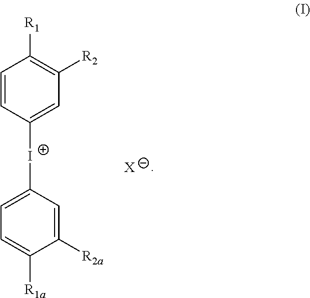

49. The negative chemically amplified EUV or e-beam photoresist composition of claim 47 wherein 1c) is a compound of structure (Ia) wherein, R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

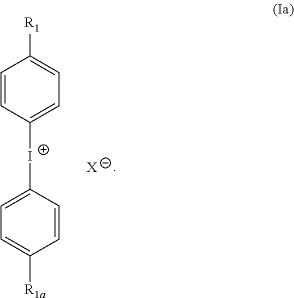

50. The negative chemically amplified EUV or e-beam photoresist composition of claim 47 wherein 1c) is a compound of a compound of structure (Ib) wherein, R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

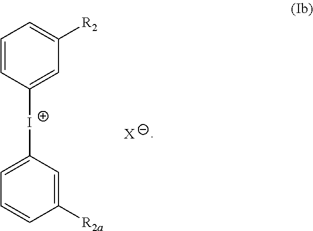

51. A process of forming a negative image with a negative photoresist by EUV or e beam exposure, comprising step ib) to vib)
ib) coating the negative chemically amplified EUV or e-beam photoresist composition of claim 47 on a substrate, to form a coated film,
iib) baking said coated film to form a baked coated film,
iiib) exposing regions of the baked coated film through a mask with EUV or e-beam radiation, forming exposed and unexposed regions,
ivb) an optional post exposure baking step,
vb) developing away the unexposed regions with an aqueous base or organic solvent developer forming a negative image pattern in said coated photoresist on the substrate,
vib) etching the substrate with a plasma or a chemical etchant using said negative image pattern as a mask, forming a negative image in the substrate.

52. A negative chemically amplified EUV or e-beam photoresist composition comprising,
1g) a compound selected from the group consisting of 1-1), 1-2), 1-3), and 1-4);
1-1) a compound of structure (I), wherein
R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,
1-2) a compound of structure (Ia) wherein,
R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-3) a compound of structure (Ib) wherein,
R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,
1-4) a compound of structure (Ic) wherein,
R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate. 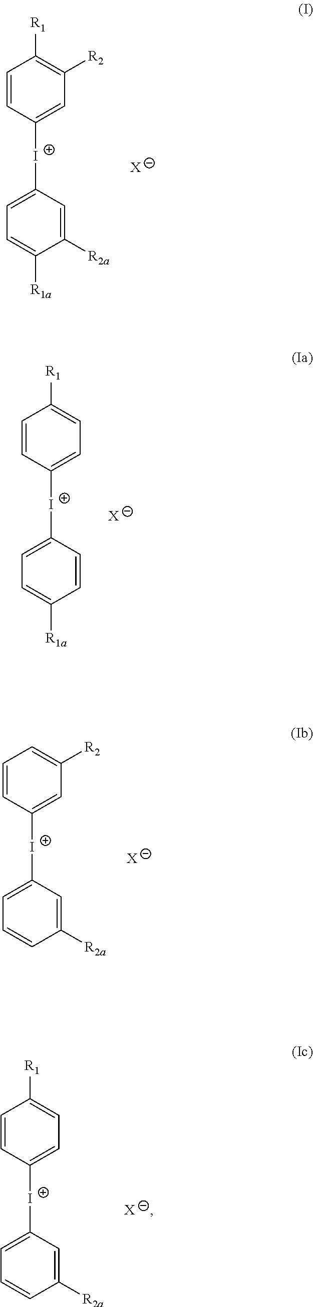
2g) a molecular glass compound comprising from 3 to 5 crosslinking moieties selected from oxiranes, oxetanes or mixtures thereof which undergo crosslinking under the influence of acid formed by irradiation of component 1a),
3g) an optional acid quencher component,
4g) an organic spin coating solvent.

53. The composition of claim 52, where said molecular glass compound has structure (II),

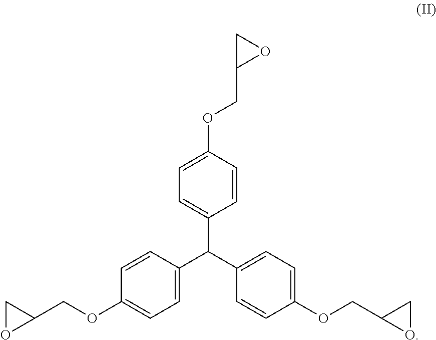 [SMILES: c1cc(C(c2ccc(OCC3CO3)cc2)c2ccc(OCC3CO3)cc2)ccc1OCC1CO1]

54. A process of forming negative image with a negative photoresist by EUV or e beam exposure, comprising step ic) to vic)
ic) coating the negative chemically amplified EUV photoresist or e-beam composition of claim 52 on a substrate, to form a coated film,
iic) baking said coated film to form a baked coated film,
iiic) exposing regions of the baked coated film through a mask with EUV or e-beam radiation, forming exposed and unexposed regions,
ivc) an optional post exposure baking step,
vc) developing away the unexposed regions with an organic solvent developer forming a negative image pattern in said coated molecular glass on the substrate,
vic) etching the substrate with a plasma or a chemical etchant using said negative image pattern as a mask, forming a negative image in the substrate.

55. (canceled)

56. (canceled)

57. The positive chemically amplified EUV or e-beam photoresist composition of claim 42 wherein 1) is a compound of a compound of structure (Ib) wherein, R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

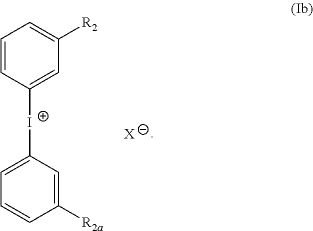

58. The positive chemically amplified EUV or e-beam photoresist composition of claim 42 wherein 1) is a compound of structure (Ic) wherein, R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

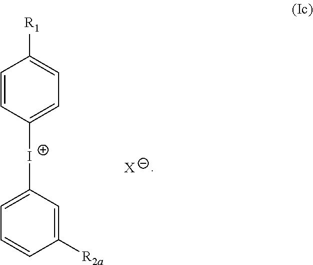

59. The negative chemically amplified EUV or e-beam photoresist composition of claim 47 wherein 1c) is a compound of structure (Ic) wherein, R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

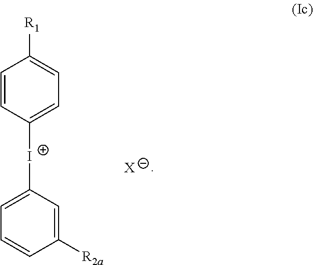

60. The negative chemically amplified EUV or e-beam photoresist composition of claim 52, wherein 1g) is a compound a compound of structure (I), wherein R₁, R₂, R₁ₐ and R₂ₐ are independently selected from the group consisting of H, nitro, cyano, and an alkylsulfonyl, wherein at least two of R₁, R₂, R₁ₐ and R₂ₐ are independently selected from nitro, cyano, and an alkylsulfonyl, and X⁻ and is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonates, naphthalenesulfonate, and/or camphorsulfonate,

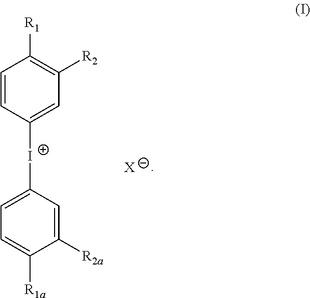

61. The negative chemically amplified EUV or e-beam photoresist composition of claim 52, wherein 1g) is a compound of structure (Ia) wherein, R₁ and R₁ₐ, are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

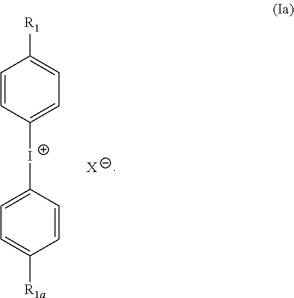

62. The negative chemically amplified EUV or e-beam photoresist composition of claim 52, wherein 1g) is a compound of structure (Ib) wherein, R₂, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate,

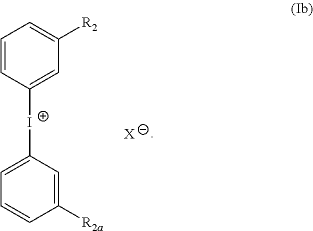

63. The negative chemically amplified EUV or e-beam photoresist composition of claim 52, wherein 1g) is a compound of structure (Ic) wherein, R₁, and R₂ₐ are independently selected from the group consisting of nitro, cyano, and an alkylsulfonyl, and X⁻ is an anion of an acid with a pKₐ lower than 0, and is not a halide, tosylate, trifluoromethylsulfonate, tetrafluoroborate, an aryl-substituted borate, hexafluorophosphate, hexafluoroarsenate, acetate, trifluoroacetate, methane sulfonate, C-2 to C-20 linear unsubstituted alkyl sulfonate, naphthalenesulfonate, and/or camphorsulfonate, [chemical structure]
